(19) United States
(12) Patent Application Publication
(10) Pub. No.: US 2026/0026199 A1
(43) Pub. Date: Jan. 22, 2026

(54) DISPLAY DEVICE AND ELECTRONIC DEVICE INCLUDING DISPLAY DEVICE

(71) Applicant: Samsung Display Co., LTD., Yongin-si (KR)

(72) Inventor: Hyun Eok SHIN, Yongin-si (KR)

(73) Assignee: Samsung Display Co., LTD., Yongin-si (KR)

(21) Appl. No.: 19/173,061

(22) Filed: Apr. 8, 2025

(30) Foreign Application Priority Data
Jul. 22, 2024 (KR) 10-2024-0096055

(51) Int. Cl. H10K 59/122; H10K 59/12; H10K 59/80

(52) U.S. Cl. CPC H10K 59/122; H10K 59/1201; H10K 59/80522

(57) ABSTRACT

A display device includes an anode electrode disposed on a substrate, an emission layer disposed on the anode electrode, a cathode electrode disposed on the emission layer, an insulating partition wall disposed between the substrate and the anode electrode, overlapping the anode electrode in a plan view, and having an area less than an area of the anode electrode in a plan view, and a connection electrode connected to the cathode electrode, generally surrounding the emission layer, the cathode electrode, and the insulating partition wall, and extending on the substrate.

### CROSS REFERENCE TO RELATED APPLICATION(S)

This application claims priority to and benefits of Korean Patent Application No. 10-2024-0096055 under 35 U.S.C. § 119, filed on Jul. 22, 2024, in the Korean Intellectual Property Office (KIPO), the entire contents of which are incorporated herein by reference.

### BACKGROUND

### 1. Technical Field

The disclosure relates to a display device, a method of manufacturing the same, and an electronic device including the display device.

### 2. Description of the Related Art

As information technology develops, the importance of a display device which is a connection medium between a user and information is highlighted. In response to this, the use of the display device such as a liquid crystal display device and an organic light emitting display device is increasing.

### SUMMARY

An object to be solved by the disclosure is to provide a display device with improved reliability.

Another object to be solved by the disclosure is to provide a method of manufacturing the display device.

Objects of the disclosure are not limited to the object described above, and other technical objects which are not described may be clearly understood by those skilled in the art from the description below.

According to embodiments of the disclosure, a display device may include an anode electrode disposed on a substrate, an emission layer disposed on the anode electrode, a cathode electrode disposed on the emission layer, an insulating partition wall disposed between the substrate and the anode electrode, overlapping the anode electrode in a plan view, and having an area less than an area of the anode electrode in a plan view, and a connection electrode connected to the cathode electrode, generally surrounding the emission layer, the cathode electrode, and the insulating partition wall, and extending on the substrate.

In an embodiment, the display device may further include an insulating layer disposed between the substrate and the insulating partition wall.

In an embodiment, the insulating partition wall may protrude from the insulating layer, and the anode electrode may be spaced apart from the insulating layer by the insulating partition wall.

In an embodiment, the connection electrode may include an auxiliary electrode disposed on the cathode electrode and directly contacting the cathode electrode, a partition wall pattern surrounding the insulating partition wall and connected to the auxiliary electrode, and a connection line disposed between the insulating layer and the partition wall pattern, extending on the insulating layer, and connected to the partition wall pattern.

In an embodiment, the auxiliary electrode may include a transparent conductive oxide (TCO).

In an embodiment, the display device may further include an insulating film disposed between the insulating partition wall and the anode electrode and disposed between the partition wall pattern and the anode electrode.

In an embodiment, the display device may further include a sub-electrode disposed between the anode electrode and the insulating film.

In an embodiment, the display device may further include a circuit element disposed between the substrate and the insulating layer and connected to at least one of the anode electrode and the sub-electrode.

In an embodiment, a contact hole for connection between the anode electrode and the sub-electrode and the circuit element may be defined in the insulating film, the insulating partition wall, and the insulating layer.

In an embodiment, the display device may further include a pixel defining film surrounding an edge of the anode electrode and contacting the insulating film.

In an embodiment, the display device may further include an insulating pattern disposed between the anode electrode and the emission layer and overlapping the contact hole in a plan view.

In an embodiment, the insulating pattern and the pixel defining film may include a same material.

According to an embodiment of the disclosure, a display device may include anode electrodes disposed on a substrate, respectively overlapping sub-pixel areas in a plan view, and spaced apart from each other, emission layers respectively disposed on the anode electrodes, cathode electrodes respectively disposed on the emission layers and spaced apart from each other, insulating partition walls disposed between the substrate and the anode electrodes, respectively overlapping the anode electrodes in a plan view, and spaced apart from each other, and a connection electrode connecting the cathode electrodes to each other.

In an embodiment, the connection electrode may include auxiliary electrodes respectively disposed on the cathode electrodes and respectively directly contacting the cathode electrodes, partition wall patterns respectively surrounding the insulating partition walls and respectively connected to the auxiliary electrodes overlapping each other in a plan view, and a connection line disposed between the substrate and the partition wall patterns and connecting the partition wall patterns to each other.

In an embodiment, the connection line may be disposed between the substrate and the insulating partition walls and may entirely extend on the substrate except for portions overlapping the insulating partition walls in a plan view.

According to an embodiment of the disclosure, an electronic device may include a processor to provide input image data; and a display device to display an image based on the input image data. The display device may include an anode electrode disposed on a substrate, an emission layer disposed on the anode electrode, a cathode electrode disposed on the emission layer, an insulating partition wall disposed between the substrate and the anode electrode, overlapping the anode electrode in a plan view, and having an area less than an area of the anode electrode in a plan view, and a connection electrode connected to the cathode electrode, generally surrounding the emission layer, the cathode electrode, and the insulating partition wall, and extending on the substrate.

In an embodiment, the electronic device may be at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.

Specific details of other embodiments are included in the detailed description and drawings.

According to the embodiment described above, since the anode electrode is separated and protruding from the insulating layer by the insulating partition wall, a shadow effect that occurs in case that the emission layer is entirely deposited on the anode electrode may be prevented. Accordingly, an emission layer of a more uniform thickness may be formed on a sub-pixel area.

In addition, when connecting the cathode electrodes to each other, the connection electrode may stably connect the cathode electrodes to each other by using the auxiliary electrode, the partition wall pattern, and the connection line that are in contact with each other and connected rather than connecting the cathode electrodes as a single extended structure. Accordingly, the reliability of the display device may be improved.

An effect according to embodiments is not limited to the contents exemplified above, and more various effects are included in the specification.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram illustrating an embodiment of a display device;

FIG. 2 is a schematic block diagram illustrating an embodiment of one of sub-pixels of FIG. 1;

FIG. 3 is a plan view illustrating an embodiment of a display panel of FIG. 1;

FIG. 4 is a schematic cross-sectional view illustrating an embodiment of the display panel of FIG. 3;

FIG. 5 is a schematic cross-sectional view illustrating another embodiment of the display panel of FIG. 3;

FIG. 6 is a schematic cross-sectional view illustrating an embodiment of one of pixels of FIG. 3;

FIG. 7 is a schematic cross-sectional view illustrating an embodiment of a contact portion between an anode electrode and a circuit element in the embodiment of FIG. 6;

FIGS. 8 to 35 are schematic cross-sectional views illustrating a method of manufacturing a display device according to embodiments of the disclosure;

FIG. 36 is a schematic block diagram illustrating an embodiment of a display system; and

FIGS. 37 to 40 are perspective views illustrating application examples of the display system of FIG. 36.

### DETAILED DESCRIPTION OF THE EMBODIMENT

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Similar reference numerals are used for similar components in describing each drawing. In the accompanying drawings, the dimensions of the structures are shown enlarged from the actual dimensions for the sake of clarity of the disclosure. Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and another portion.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanying drawings. In the following description, the singular expressions include plural expressions unless the context clearly dictates otherwise.

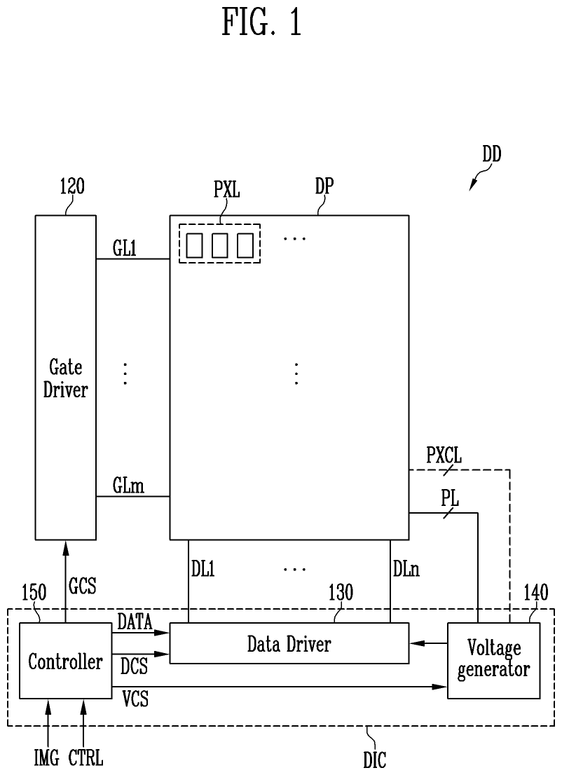

FIG. 1 is a schematic block diagram illustrating an embodiment of a display device.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, each of the sub-pixels SP may generate light such as red light, green light, blue light, cyan light, magenta light, or yellow light.

Two or more of the sub-pixels SP may configure one pixel PXL. For example, a pixel PXL may include three sub-pixels as shown in FIG. 1. As described above, the pixel PXL may emit light of various colors and various luminances according to a combination of light emitted from the sub-pixels included in the pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal indicating a start of each frame, a horizontal synchronization signal, and the like.

The gate driver 120 may be disposed on a side of the display panel DP. However, the disclosure is not limited thereto. For example, the gate driver 120 may be divided into two or more physically and/or logically divided drivers, and such drivers may be disposed on a side of the display panel DP and another side of the display panel DP opposite the side. As described above, the gate driver 120 may be disposed adjacent to the display panel DP in various shapes according to embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In an embodiment, the data control signal DCS may include a source start signal, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn using the received voltages. In case that the gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate multiple voltages and provide the generated voltages to components of the display device DD, such as the gate driver 120, the data driver 130, and the controller 150. The voltage generator 140 may generate the voltages by receiving an input voltage from an outside of the display device DD and regulating the received voltage.

The voltage generator 140 may generate a first power voltage and a second power voltage. The first and second power voltages may be provided to the sub-pixels SP through power lines PL. In another embodiment, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation for sensing electrical characteristics of transistors and/or light emitting elements of the sub-pixels SP, a reference voltage may be applied to the first to n-th data lines DLI to DLn, and the voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In an embodiment, the voltage generator 140 may provide the pixel control signals to the sub-pixels SP through pixel control lines PXCL. In FIG. 1, the pixel control lines PXCL are connected between the voltage generator 140 and the display panel DP, but the disclosure is not limited thereto. For example, the pixel control lines PXCL may be connected between the gate driver 120 and the display panel DP, and the pixel control signals may be transmitted from the voltage generator 140 to the pixel control lines PXCL through the gate driver 120.

The controller 150 may control overall operations of the display device DD. The controller 150 may receive input image data IMG and a control signal CTRL corresponding to the input image data IMG from the outside. The controller 150 may provide the gate control signal GCS, the data control signal DCS, and the voltage control signal VCS in response to the control signal CTRL.

The controller 150 may convert the input image data IMG suitable for the display device DD or the display panel DP and output the image data DATA. In an embodiment, the controller 150 may output the image data DATA by aligning the input image data IMG suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC, and the data driver 130, the voltage generator 140, and the controller 150 may be functionally divided components in one driver integrated circuit DIC. In another embodiment, at least one of the data driver 130, the voltage generator 140, and the controller 150 may be provided as a component distinguished from the driver integrated circuit DIC.

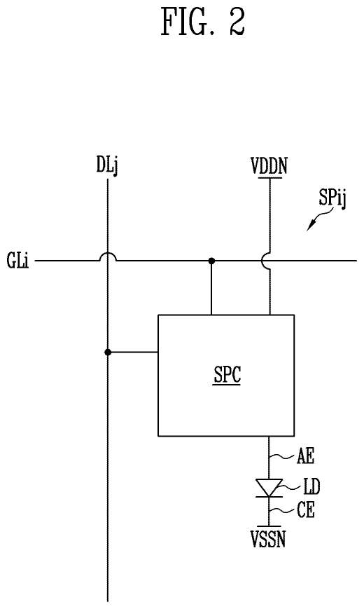

FIG. 2 is a schematic block diagram illustrating an embodiment of one of the sub-pixels of FIG. 1. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an embodiment.

Referring to FIG. 2, a sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL of FIG. 1 and receive the first power voltage. The second power voltage node VSSN may be connected to another one of the power lines PL of FIG. 1 and receive the second power voltage. The first power voltage may have a voltage level higher than a voltage level of the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may be configured to emit light according to a current flowing from the anode electrode AE to the cathode electrode CE.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to a gate signal received through the i-th gate line GLi, the sub-pixel circuit SPC may control the light emitting element LD to emit light according to a data signal received through the j-th data line DLj. In an embodiment, the sub-pixel circuit SPC may be further connected to the pixel control lines PXCL of FIG. 1, and the sub-pixel circuit SPC may control the light emitting element LD in further response to the pixel control signals received through the pixel control lines PXCL.

For such operations, the sub-pixel circuit SPC may include circuit elements, for example, transistors and one or more capacitors.

The transistors of the sub-pixel circuit SPC may include P-type transistors and/or N-type transistors. In an embodiment, the transistors of the sub-pixel circuit SPC may include a metal oxide silicon field effect transistor (MOSFET). In an embodiment, the transistors of the sub-pixel circuit SPC may include an amorphous silicon semiconductor, a monocrystalline silicon, polycrystalline silicon semiconductor, an oxide semiconductor, or the like.

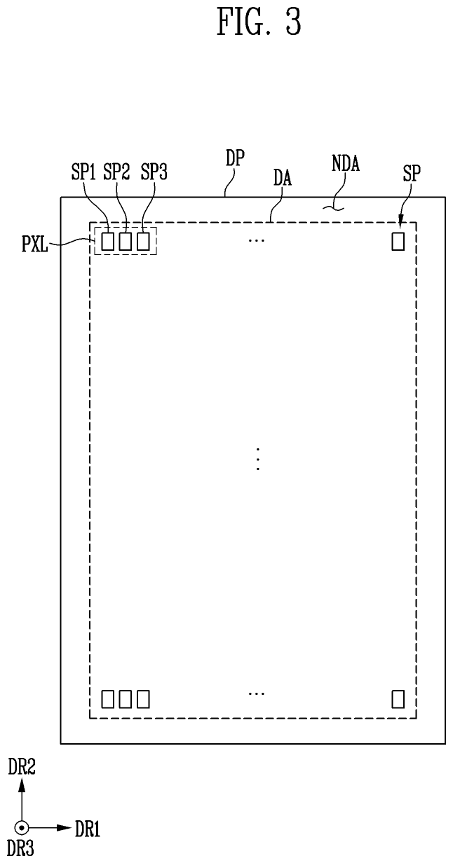

FIG. 3 is a plan view illustrating an embodiment of the display panel of FIG. 1.

Referring to FIG. 3, the display panel DP may include a display area DA and a non-display arca NDA. The display panel DP may display an image through the display area DA. The non-display area NDA may be disposed adjacent to the display area DA.

The display panel DP may include sub-pixels SP in the display area DA. The sub-pixels SP may be arranged in a first direction DR1 and a second direction DR2 intersecting the first direction DR1. For example, the sub-pixels SP may be arranged in a matrix form in the first direction DR1 and the second direction DR2. For example, the sub-pixels SP may be arranged in a zigzag form along the first direction DR1 and the second direction DR2. An arrangement of the sub-pixels SP may vary according to embodiments. The first direction DRI may be a row direction, and the second direction DR2 may be a column direction.

Two or more of the sub-pixels SP may configure one pixel PXL. In FIG. 3, the pixel PXL includes three sub-pixels SP1 to SP3, but the disclosure is not limited thereto. For example, the pixel PXL may include two sub-pixels. Hereinafter, for convenience of description, an embodiment that the pixel PXL includes the first to third sub-pixels SP1 to SP3 is described.

Each of the first to third sub-pixels SP1 to SP3 may generate light of one of various colors such as red, green, blue, cyan, magenta, and yellow. Hereinafter, for clear and concise description, an embodiment that the first sub-pixel SP1 is configured to generate light of a red color, the second sub-pixel SP2 is configured to generate light of a green color, and the third sub-pixel SP3 is configured to generate light of a blue color is described.

Each of the first to third sub-pixels SP1 to SP3 may include at least one light emitting element configured to generate light. In an embodiment, the light emitting elements of the first to third sub-pixels SP1 to SP3 may generate light of a same color. For example, the light emitting elements of the first to third sub-pixels SP1 to SP3 may generate the light of the blue color. In another embodiment, the light emitting elements of the first to third sub-pixels SP1 to SP3 may generate light of different colors. For example, the light emitting elements of the first to third sub-pixels SP1 to SP3 may generate the light of the red color, the green color, and the blue color, respectively.

As the display panel DP, a display panel capable of self-emission, such as a light emitting diode display panel (LED display panel) using a micro scale or nano scale of light emitting diode as the light emitting element, an organic light emitting display panel (OLED panel) using an organic light emitting diode as the light emitting element, or the like, may be used.

A component for controlling the sub-pixels SP may be disposed in the non-display area NDA. Lines connected to the sub-pixels SP, for example, the first to m-th gate lines GLI to GLm, the first to n-th data lines DLI to DLn, the power lines PL, and the pixel control lines PXCL of FIG. 1 may be disposed in the non-display area NDA.

At least one of the gate driver 120, the data driver 130, the voltage generator 140, and the controller 150 of FIG. 1 may be disposed in the non-display area NDA of the display panel DP. In an embodiment, the gate driver 120 may be disposed in the non-display area NDA, the data driver 130, the voltage generator 140, and the controller 150 may be implemented as a driver integrated circuit DIC of FIG. 1, separate from the display panel DP, and the driver integrated circuit DIC may be connected to the lines disposed in the non-display area NDA. In another embodiment, the gate driver 120 may be implemented as one integrated circuit separate from the display panel DP, together with the data driver 130, the voltage generator 140, and the controller 150.

The display area DA may have various shapes in a plan view. In an embodiment, the display area DA may have a closed loop shape including sides of a straight line and/or a curved line. For example, the display area DA may have shapes of a polygon, a circle, a semicircle, an ellipse, and the like.

In an embodiment, the display panel DP may have a flat display surface. In another embodiment, the display panel DP may have a display surface that is at least partially round. In an embodiment, the display panel DP may be bendable, foldable, or rollable, and the display panel DP and/or a substrate of the display panel DP may include materials having a flexible property.

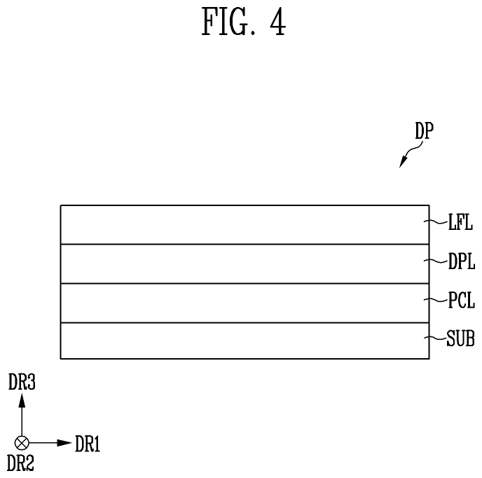

FIG. 4 is a schematic cross-sectional view illustrating an embodiment of the display panel of FIG. 3.

Referring to FIG. 4, the display panel DP may include a substrate SUB, and a pixel circuit layer PCL, a display element layer DPL, and a light functional layer LFL sequentially stacked on the substrate SUB in a third direction DR3 intersecting the first and second directions DR1 and DR2.

The substrate SUB may be formed of an insulating material such as glass or a resin. For example, the substrate SUB may include a glass substrate. In another embodiment, the substrate SUB may include a polyimide (PI) substrate. In another embodiment, the substrate SUB may include a silicon wafer substrate formed using a semiconductor process.

In an embodiment, the substrate SUB may be formed of a flexible material that may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the disclosure is not limited thereto.

The pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, lines, and the like.

The circuit elements of the pixel circuit layer PCL may include the sub-pixel circuit SPC (refer to FIG. 2) of each of the sub-pixels SP of FIG. 3. In other words, the circuit elements of the pixel circuit layer PCL may be provided as transistors and one or more capacitors of the sub-pixel circuit SPC.

The lines of the pixel circuit layer PCL may include lines connected to the sub-pixels SP. The lines of the pixel circuit layer PCL may include various signal lines and/or voltage lines to drive the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may change a wavelength (or color) of light emitted from the display element layer DPL. The light functional layer LFL may further include light scattering patterns having the scattering particles. In an embodiment, the light conversion patterns and the light scattering patterns may be omitted.

The light functional layer LFL may include a color filter layer including color filters. The color filter may selectively transmit light of a specific wavelength (or a specific color). In an embodiment, the color filter layer may be omitted.

Although not illustrated, a window for protecting an exposed surface (or an upper surface) of the display panel DP may be provided on the light functional layer LFL. The window may protect the display panel DP from external shock. The window may be coupled to the light functional layer LFL by an optically transparent adhesive (or cohesive) member. The window may have a multi-layer structure including a glass substrate, a plastic film, and/or a plastic substrate. The multi-layer structure may be formed through a continuous process or an adhesion process using an adhesive layer. All or a portion of the window may be flexible.

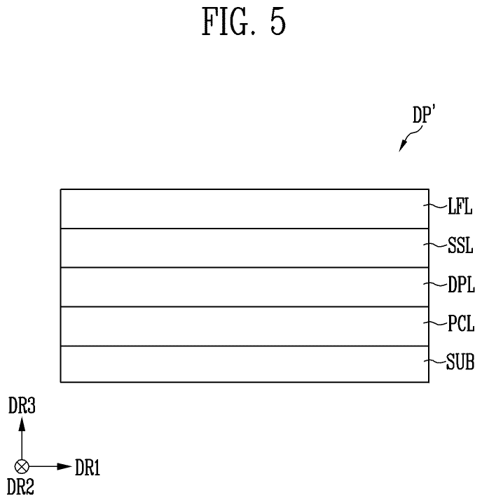

FIG. 5 is a schematic cross-sectional view illustrating another embodiment of the display panel of FIG. 3.

Referring to FIG. 5, the display panel DP′ may include the substrate SUB, the pixel circuit layer PCL, the display element layer DPL, an input sensing layer SSL, and the light functional layer LFL. The substrate SUB, the pixel circuit layer PCL, the display element layer DPL, and the light functional layer LFL may be configured similarly to the substrate SUB, the pixel circuit layer PCL, the display element layer DPL, and the light functional layer LFL described with reference to FIG. 4, respectively. Hereinafter, an overlapping description is omitted.

The input sensing layer SSL may sense a user input on an upper surface (or a display surface) of the display panel DP′. The input sensing layer SSL may include components suitable for sensing an external object such as a user's hand, or a pen. For example, the input sensing layer SSL may include touch electrodes.

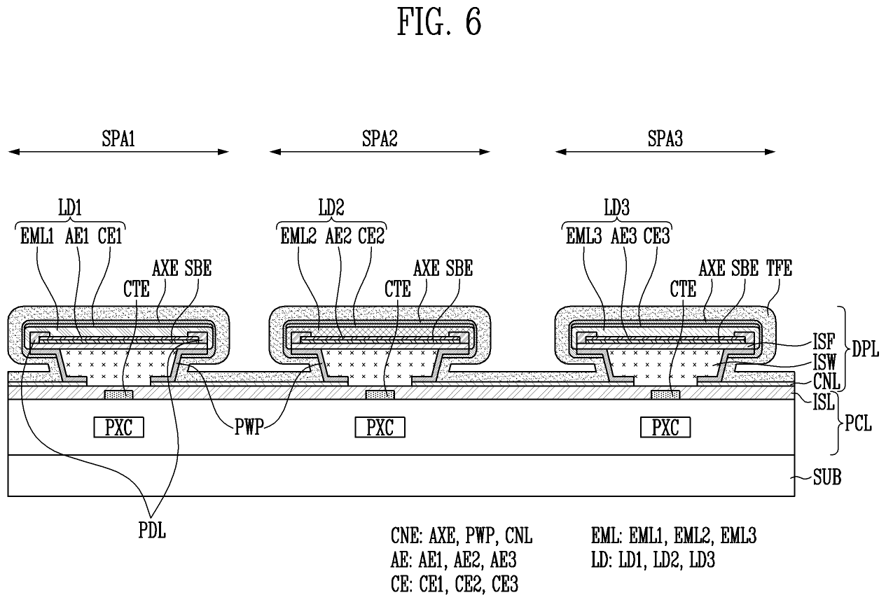

FIG. 6 is a schematic cross-sectional view illustrating an embodiment of the pixels of FIG. 3. FIG. 6 schematically illustrates only the substrate SUB, the pixel circuit layer PCL, and the display element layer DPL of FIG. 4 or 5.

Referring to FIG. 6, the display panel may include first to third sub-pixel areas SPA1 to SPA3 in which the first to third sub-pixels SP1 to SP3 of FIG. 3 are respectively disposed.

The pixel circuit layer PCL may be disposed on the substrate SUB. The pixel circuit layer PCL may include circuit elements PXC, a contact electrode CTE, and an insulating layer ISL. The pixel circuit layer PCL may further include insulating layers and semiconductor patterns and conductive patterns disposed between the insulating layers.

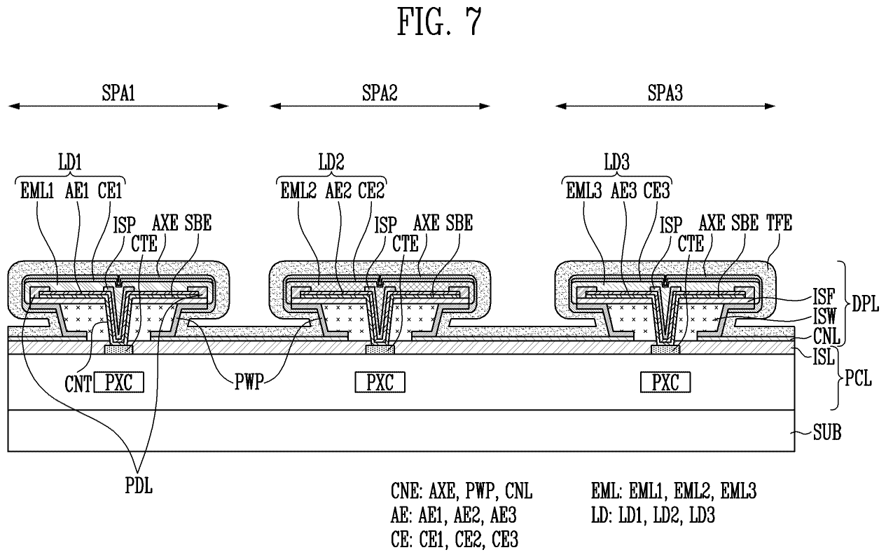

The circuit elements PXC may be disposed on the substrate SUB. The respective circuit elements PXC may be provided as transistors and capacitors of each of the sub-pixels. The contact electrodes CTE may be disposed on the circuit elements PXC. The contact electrodes CTE may be respectively connected to the circuit elements PXC and may electrically connect the light emitting elements LD and the circuit elements PXC to each other (refer to FIG. 7).

The insulating layer ISL may cover the contact electrodes CTE. The insulating layer ISL may overlap the first to third sub-pixel areas SPA1 to SPA3 in a plan view and may extend over the first to third sub-pixel areas SPA1 to SPA3. The insulating layer ISL may include an organic material.

The display element layer DPL may be disposed on the insulating layer ISL. The display element layer DPL may include insulating partition walls ISW, insulating films ISF, first to third anode electrodes AE1 to AE3, first to third emission layers EML1 to EML3, first to third cathode electrodes CE1 to CE3, a connection electrode CNE, sub-electrodes SBE, pixel defining films PDL, and an encapsulation layer TFE. The connection electrode CNE may include a connection line CNL, partition wall patterns PWP, and auxiliary electrodes AXE.

The insulating partition walls ISW may be disposed on the insulating layer ISL. The insulating partition walls ISW may overlap the first to third sub-pixel areas SPA1 to SPA3, respectively, in a plan view and the insulating partition walls ISW may be spaced apart from each other. Each of the insulating partition walls ISW may protrude from the insulating layer ISL. For example, each of the insulating partition walls ISW may be spaced apart from each other and protrude from the insulating layer ISL rather than having a shape extending on the insulating layer ISL. Each of the insulating partition walls ISW may include an organic material.

The insulating films ISF may be disposed on the insulating partition walls ISW, respectively. The insulating films ISF may respectively overlap the insulating partition walls ISW in a plan view, and the insulating films ISF may be spaced apart from each other. The area of each of the insulating films ISF may be greater than the area of each of the insulating partition walls ISW in a plan view, and each of the insulating films ISF may include an inorganic material.

The first to third anode electrodes AE1 to AE3 may be disposed on the insulating films ISF, respectively. The first to third anode electrodes AE1 to AE3 may be disposed in the first to third sub-pixel areas SPA1 to SPA3, respectively, and may overlap the insulating partition walls ISW, respectively, in a plan view, and the first to third anode electrodes AE1 to AE3 may be spaced apart from each other. Each of the first to third anode electrodes AE1 to AE3 may be provided as an anode electrode AE connected to the sub-pixel circuit SPC (refer to FIG. 2) of each of the first to third sub-pixels SP1 to SP3 of FIG. 3.

Each of the first to third anode electrodes AE1 to AE3 may be spaced apart from the insulating layer ISL by the insulating partition wall ISW. The area of each of the first to third anode electrodes AE1 to AE3 may be greater than the area of each of the insulating partition walls ISW in a plan view.

The sub-electrodes SBE may be disposed between the first to third anode electrodes AE1 to AE3 and the insulating films ISF, respectively. The sub-electrodes SBE may entirely overlap and contact (e.g., directly contact) the first to third anode electrodes AE1 to AE3, respectively. Each of the sub-electrodes SBE may include titanium.

The pixel defining films PDL may be disposed on the first to third anode electrodes AE1 to AE3, respectively. The pixel defining films PDL may surround edges of the first to third anode electrodes AE1 to AE3, respectively, and the pixel defining films PDL may be spaced apart from each other. Accordingly, the pixel defining films PDL may insulate the edges of the first to third anode electrodes AE1 to AE3 from the first to third cathode electrodes CE1 to CE3. The pixel defining films PDL may contact the insulating films ISF under the first to third anode electrodes AE1 to AE3, respectively, and thus the edges of the first to third anode electrodes AE1 to AE3 may be covered through the pixel defining films PDL and the insulating films ISF.

The first to third emission layers EML1 to EML3 may be disposed on the first to third anode electrodes AE1 to AE3 and the pixel defining films PDL, respectively. The first to third emission layers EML1 to EML3 may overlap the first to third anode electrodes AE1 to AE3, respectively, in a plan view, and the first to third emission layers EML1 to EML3 may be spaced apart from each other. For example, the first to third emission layers EML1 to EML3 may not overlap an area between the first to third sub-pixel regions SPA1 to SPA3, and may be separated from each other.

For example, the first to third emission layers EML1 to EML3 may generate the light of the red, green, and blue colors, respectively. However, the disclosure is not limited thereto, and in another embodiment, all of first to third light emitting elements LD1 to LD3 may generate the light of the blue color.

The first to third cathode electrodes CE1 to CE3 may be disposed on the first to third emission layers EML1 to EML3, respectively. The first to third cathode electrodes CE1 to CE3 may overlap the first to third emission layers EML1 to EML3, respectively, in a plan view, and the first to third cathode electrodes CE1 to CE3 may be spaced apart from each other. For example, the first to third cathode electrodes CE1 to CE3 may not overlap an area between the first to third sub-pixel areas SPA1 to SPA3, and may be separated from each other.

Each of the first to third cathode electrodes CE1 to CE3 may be provided as the cathode electrode CE (refer to FIG. 2) connected to the sub-pixel circuit SPC (refer to FIG. 2) of each of the first to third sub-pixels SP1 to SP3 of FIG. 3.

The first anode electrode AE1, the first emission layer EML1, and the first cathode electrode CE1 may configure the first light emitting element LD1, the second anode electrode AE2, the second emission layer EML2, and the second cathode electrode CE2 may configure the second light emitting element LD2, and the third anode electrode AE3, the third emission layer EML3, and the third cathode electrode CE3 may configure the third light emitting element LD3. Each of the first to third light emitting elements LD1 to LD3 may be provided as the light emitting element LD (refer to FIG. 2) connected to the sub-pixel circuit SPC (refer to FIG. 2) of each of the first to third sub-pixels SP1 to SP3 of FIG. 3.

Each of the first to third light emitting elements LD1 to LD3 may have the area greater than the planar area of the insulating partition wall ISW overlapping each other in a plan view. For example, each of the first to third light emitting elements LD1 to LD3 may be spaced apart from the insulating layer ISL by the insulating partition wall ISW, and may configure a tip structure that protrudes since the area is greater than the area of the insulating partition wall ISW in a plan view.

In an embodiment, the connection electrode CNE may be disposed on the insulating layer ISL and entirely surround the insulating partition walls ISW, the insulating films ISF, the pixel defining films PDL, and the first to third light emitting elements LD1 to LD3 in a plan view. The connection electrode CNE may be connected to the first to third cathode electrodes CE1 to CE3 and may entirely extend on the substrate SUB. Therefore, the connection electrode CNE may connect the first to third cathode electrodes CE1 to CE3 to each other. The connection electrode CNE may be connected to the cathode electrode CE to entirely connect the cathode electrode CE included in each of the first to third sub-pixels SP1 to SP3 in the display panel, and may generally extend on the insulating layer ISL.

The connection electrode CNE may include auxiliary electrodes AXE, partition wall patterns PWP, and a connection line CNL.

The auxiliary electrodes AXE may be disposed on the first to third cathode electrodes CE1 to CE3, respectively. The auxiliary electrodes AXE may contact (e.g., directly contact) and may be connected to the first to third cathode electrodes CE1 to CE3, respectively. Each of the auxiliary electrodes AXE may surround the light emitting element LD and extend to a lower portion of the insulating film ISF. Each of the auxiliary electrodes AXE may include a transparent conductive oxide (TCO). For example, each of the auxiliary electrodes AXE may include indium zinc oxide (IZO).

The partition wall patterns PWP may surround the insulating partition walls ISW, respectively, and may be connected to the auxiliary electrodes AXE, respectively. For example, the partition wall patterns PWP may surround side surfaces of the insulating partition walls ISW, respectively, and may contact (e.g., directly contact) the auxiliary electrodes AXE, respectively. Each of the partition wall patterns PWP may extend from a side surface of the insulating partition wall ISW to a lower portion of the insulating film ISF, and may contact (e.g., directly contact) the auxiliary electrode AXE at the lower portion of the insulating film ISF. For example, each of the partition wall patterns PWP may contact the auxiliary electrode AXE at a lower portion of the tip structure formed by each of the first to third light emitting elements LD1 to LD3.

The insulating films ISF may be disposed between overlapping ones of the partition wall patterns PWP and the first to third anode electrodes AE1 to AE3. Therefore, the first to third anode electrodes AE1 to AE3 may be electrically insulated from the first to third cathode electrodes CE1 to CE3 by the insulating films ISF, respectively.

Each of the partition wall patterns PWP may also surround a portion of a lower surface of the insulating partition wall ISW. For example, each of the partition wall patterns PWP may extend from the side surface of the insulating partition wall ISW to the lower surface of the insulating partition wall ISW, and may be disposed between the insulating layer ISL and the insulating partition wall ISW. Accordingly, each of the partition wall patterns PWP may contact (e.g., directly contact) and may be connected to the connection line CNL extending on the insulating layer ISL.

Each of the partition wall patterns PWP may include a metal. For example, each of the partition wall patterns PWP may have a single-layer or multi-layer structure, and each layer may include at least one of titanium, molybdenum, and aluminum. However, the disclosure is not limited thereto.

The connection line CNL may be disposed between the insulating layer ISL and the insulating partition walls ISW, and may extend on the insulating layer ISL. For example, the connection line CNL may entirely extend on the insulating layer ISL other than an area the insulating partition walls ISW and the insulating layer ISL contacting each other. The connection line CNL may be disposed between the insulating layer ISL and the partition wall patterns PWP. For example, the connection line CNL may be connected to the partition wall patterns PWP extending to a lower surface of the insulating partition walls ISW. Accordingly, the connection line CNL may connect the partition wall patterns PWP spaced apart from each other.

In an embodiment, the auxiliary electrode AXE, the partition wall pattern PWP, and the connection line CNL included in the connection electrode CNE may contact (e.g., directly contact) each other and may be connected, and thus the cathode electrodes CE spaced apart from each other may be stably connected to each other in the pixels PXL including the first to third sub-pixels SP1 to SP3.

The encapsulation layer TFE may be disposed on the connection electrode CNE. The encapsulation layer TFE may entirely cover the connection electrode CNE. The encapsulation layer TFE may be configured to prevent oxygen, moisture, and/or the like from penetrating into the first to third light emitting elements LD1 to LD3. The encapsulation layer TFE may have a structure in which at least one organic film and at least one inorganic film are stacked.

In an embodiment, since the light emitting element LD is separated from the insulating layer ISL and protrudes by the insulating partition wall ISW, and the auxiliary electrode AXE, the partition wall pattern PWP, and the connection line CNL included in the connection electrode CNE contact (e.g., directly contact) each other and are connected to each other, the cathode electrode CE may be entirely connected in the pixels PXL including the first to third sub-pixels SP1 to SP3. Accordingly, a shadow effect may be prevented, and a more uniform thickness of the emission layer EML may be secured. By connecting the cathode electrodes CE to each other using the auxiliary electrode AXE, the partition wall pattern PWP, and the connection line CNL contact (e.g., directly contact) each other rather than connecting the cathode electrodes CE with a single extended structure, a disconnection and a resistance increase due to step coverage may be prevented. Therefore, the connection electrode CNE may stably connect the cathode electrodes CE to each other, and reliability of the display device may be improved.

FIG. 7 is a schematic cross-sectional view illustrating an embodiment of a contact portion between the anode electrode and the circuit element in the embodiment of FIG. 6. Therefore, a content that may overlap the content described above is briefly described or is not repeated.

Referring to FIG. 7, the circuit elements PXC may be connected to the display element layer DPL through contact electrodes CTE. Each of the contact electrodes CTE may be connected to at least one of the anode electrode AE and the sub-electrode SBE. To this end, contact holes CNT for connection between the anode electrode AE and the sub-electrode SBE and the contact electrode CTE may be defined in the insulating layer ISL, the insulating partition walls ISW, and the insulating films ISF, respectively. For example, a contact hole CNT may be defined entirely in the insulating layer ISL, the insulating partition wall ISW, and the insulating film ISF overlapping each other. At least one of the anode electrode AE and the sub-electrode SBE may contact (e.g., directly contact) the contact electrode CTE through each of the contact holes CNT and may be connected to the pixel circuit layer PCL.

The sub-electrode SBE may entirely overlap the anode electrode AE in a plan view, may be disposed between the anode electrode AE and the contact electrode CTE, and may function to stably connect the anode electrode AE and the contact electrode CTE.

Insulating patterns ISP may be disposed between the first to third anode electrodes AE1 to AE3 and the first to third emission layers EML1 to EML3, respectively. The insulating patterns ISP may overlap the contact holes CNT in a plan view, respectively. The planar arca of each of the insulating patterns ISP may be less than the planar area of each of the first to third anode electrodes AE1 to AE3 in a plan view. Therefore, each of the insulating patterns ISP may be disposed only in a portion overlapping the contact hole CNT between the anode electrode AE and the emission layer EML. For example, each of the insulating patterns ISP may insulate the anode electrode AE and the cathode electrode CE from each other in a portion overlapping the contact hole CNT.

Each of the insulating patterns ISP and the pixel defining film PDL may include a same material, and may be disposed in a same layer. For example, each of the insulating patterns ISP and the pixel defining film PDL may be formed in a same process.

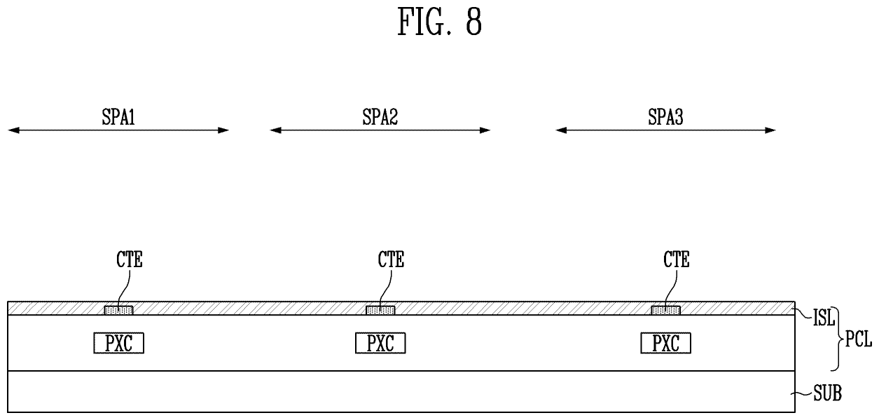

FIGS. 8 to 35 are schematic cross-sectional views illustrating a method of manufacturing a display device according to embodiments of the disclosure. FIGS. 8 to 35 schematically illustrate a method of manufacturing the display device DD according to the embodiment described above with reference to FIGS. 1 to 7. Therefore, a content that may overlap the content described above is briefly described or is not repeated.

Referring to FIG. 8, the pixel circuit layer PCL may be formed on the substrate SUB. For example, the circuit elements PXC may be formed on the substrate SUB. The contact electrodes CTE respectively overlapping the first to third sub-pixel areas SPA1 to SPA3 in a plan view may be formed on the circuit elements PXC. The insulating layer ISL may be formed on the circuit elements PXC and cover the contact electrodes CTE. The insulating layer ISL may be formed of an organic material.

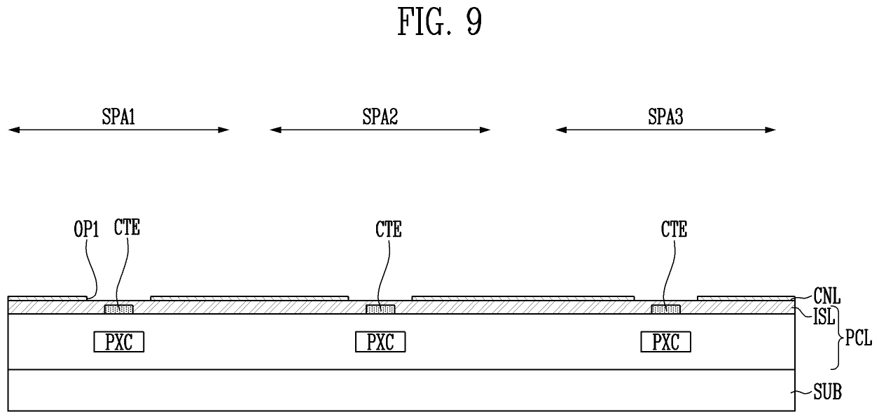

Referring to FIG. 9, the connection line CNL may be entirely formed on the insulating layer ISL. First openings OP1 respectively overlapping the first to third sub-pixel areas SPA1 to SPA3 may be formed in the connection line CNL. The first openings OP1 may overlap the contact electrodes CTE in a plan view, respectively.

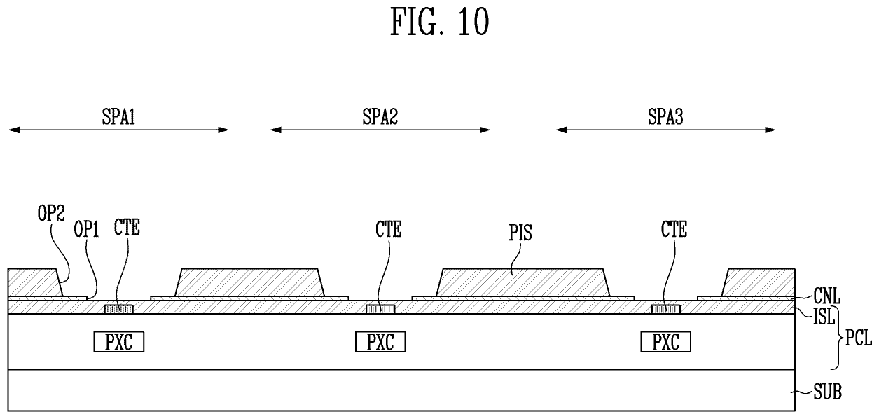

Referring to FIG. 10, a preliminary insulating layer PIS may be entirely formed on the connection line CNL. Second openings OP2 respectively overlapping the first openings OP1 in a plan view may be formed in the preliminary insulating layer PIS. The planar area of each of the second openings OP2 may be greater than the planar area of each of the first openings OP1 in a plan view. Therefore, the connection line CNL may be partially exposed to an outside through the second openings OP2 of the preliminary insulating layer PIS.

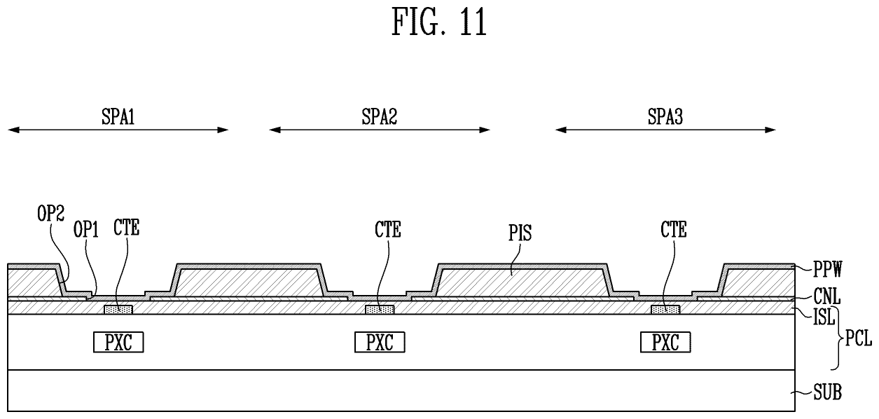

Referring to FIG. 11, a preliminary partition wall pattern PPW may be entirely formed on the insulating layer ISL, the connection line CNL, and the preliminary insulating layer PIS. The preliminary partition wall pattern PPW may be formed as a single-layer or multi-layer structure, and each layer may be formed of at least one of titanium, molybdenum, and aluminum. However, the disclosure is not limited thereto.

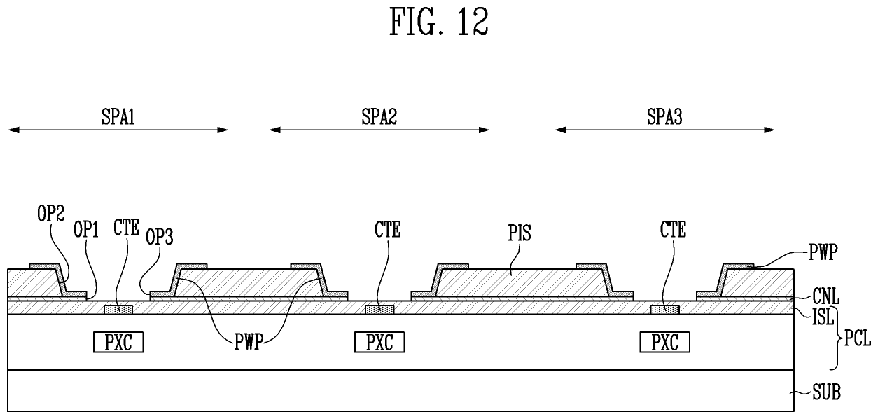

Referring to FIG. 12, the preliminary partition wall pattern PPW may be patterned to form the partition wall patterns PWP and third openings OP3. The partition wall patterns PWP may overlap the first to third sub-pixel areas SPA1 to SPA3 in a plan view, respectively, and the partition wall patterns PWP may be spaced apart from each other. The third openings OP3 may overlap the second openings OP2 in a plan view, respectively.

Each of the partition wall patterns PWP may be formed in a structure extending from a side surface of the preliminary insulating layer PIS defining each of the second openings OP2 to an upper surface of the preliminary insulating layer PIS, and may be formed in a structure extending to an upper surface of the connection line CNL exposed by each of the second openings OP2. Accordingly, each of the partition wall patterns PWP may contact (e.g., directly contact) the connection line CNL and may be connected to the connection line CNL.

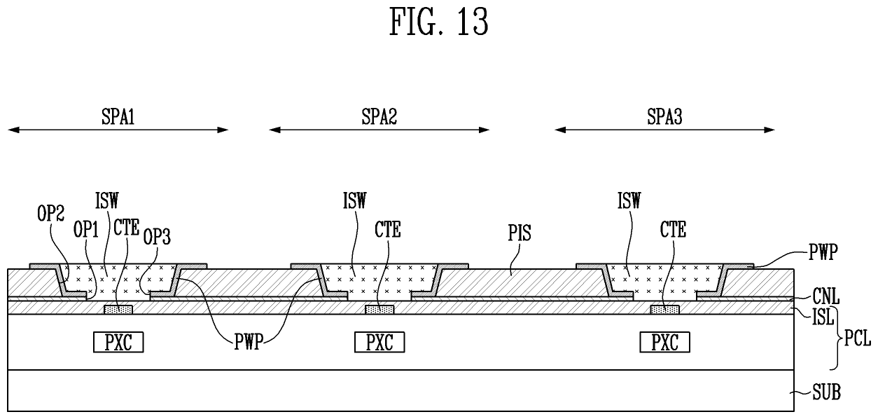

Referring to FIG. 13, the insulating partition walls ISW may be formed on the insulating layer ISL and the partition wall patterns PWP, respectively. Each of the insulating partition walls ISW may be formed on an inner side of the partition wall pattern PWP. For example, each of the insulating partition walls ISW may fill the inner side of the partition wall pattern PWP. The insulating partition walls ISW may be formed of an organic material.

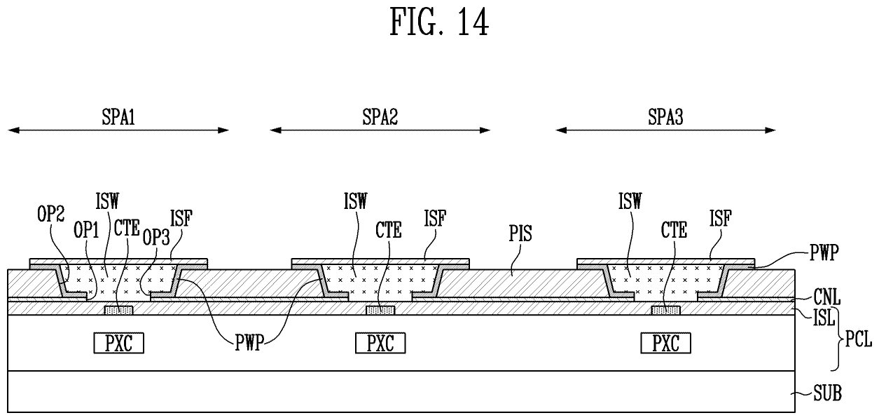

Referring to FIG. 14, the insulating films ISF may be formed on the partition wall patterns PWP and the insulating partition walls ISW, respectively. The insulating films ISF may overlap the first to third sub-pixel areas SPA1 to SPA3 in a plan view, respectively, and the insulating films ISF may be spaced apart from each other. Each of the insulating films ISF may entirely overlap the insulating partition wall ISW, and may have the area greater than the area of the overlapping insulating partition wall ISW in a plan view.

Each of the insulating films ISF may cover an upper surface of the partition wall pattern PWP extending to the upper surface of the preliminary insulating layer PIS. Each of the insulating films ISF may be formed of an inorganic material.

After forming the insulating films ISF, the contact hole CNT (refer to FIG. 7) passing through the insulating film ISF, the insulating partition wall ISW, and the insulating layer ISL may be formed in the insulating film ISF, the insulating partition wall ISW, and the insulating layer ISL. Each of the contact holes CNT may be formed as a single hole passing through all of the insulating film ISF, the insulating partition wall ISW, and the insulating layer ISL through the third opening OP3 of the partition wall pattern PWP and the first opening OP1 of the connection line CNL.

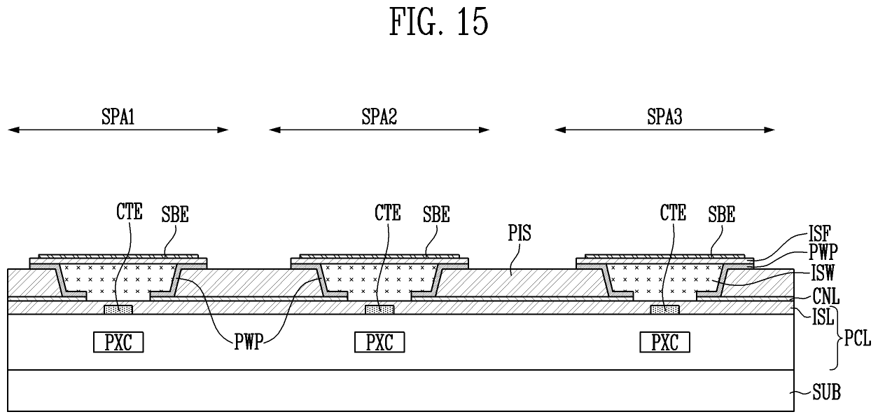

Referring to FIG. 15, the sub-electrodes SBE may be formed on the insulating films ISF, respectively. The sub-electrodes SBE may overlap the first to third sub-pixel areas SPA1 to SPA3 in a plan view, respectively, and the sub-electrodes SBE may be spaced apart from each other.

Each of the sub-electrodes SBE may be formed spaced apart from the partition wall pattern PWP with the insulating film ISF interposed between the sub-electrodes SBE and the partition wall pattern PWP, and the sub-electrodes SBE may be insulated from the partition wall pattern PWP by the insulating film ISF. Accordingly, the planar area of each of the sub-electrodes SBE may be less than the planar area of each of the insulating films ISF in a plan view. Each of the sub-electrodes SBE may be formed of titanium.

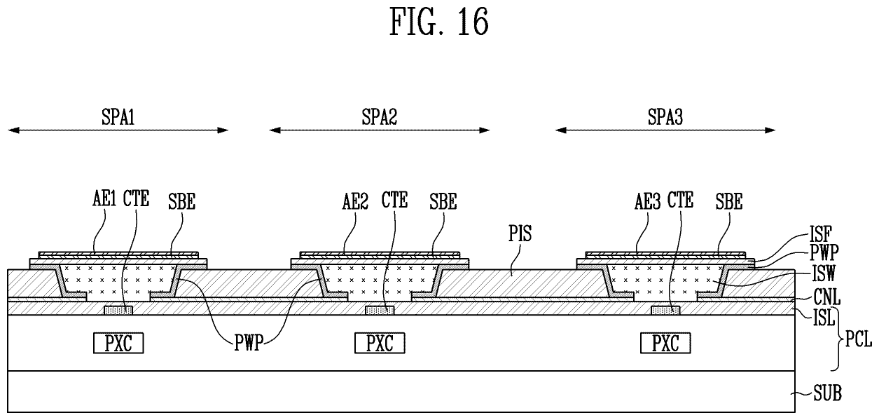

Referring to FIG. 16, the first to third anode electrodes AE1 to AE3 may be formed on the sub-electrodes SBE, respectively. The first to third anode electrodes AE1 to AE3 may overlap the first to third sub-pixel areas SPA1 to SPA3 in a plan view, respectively, and the first to third anode electrodes AE1 to AE3 may be spaced apart from each other. The first to third anode electrodes AE1 to AE3 may entirely overlap the sub-electrodes SBE overlapping each other in a plan view, and may contact each other.

The first to third anode electrodes AE1 to AE3 may be formed spaced apart from the partition wall patterns PWP with the insulating films ISF interposed between the first to third anode electrodes AE1 to AE3 and the partition wall patterns PWP, and the first to third anode electrodes AE1 to AE3 may be insulated from the partition wall patterns PWP by the insulating films ISF. For example, the planar area of each of the first to third anode electrodes AE1 to AE3 may be formed less than the planar area of each of the insulating films ISF in a plan view. Each of the first to third anode electrodes AE1 to AE3 may have the area greater than the area of the overlapping insulating partition wall ISW in a plan view, and each of the first to third anode electrodes AE1 to AE3 may be formed in a structure in which indium tin oxide and silver are alternately stacked each other.

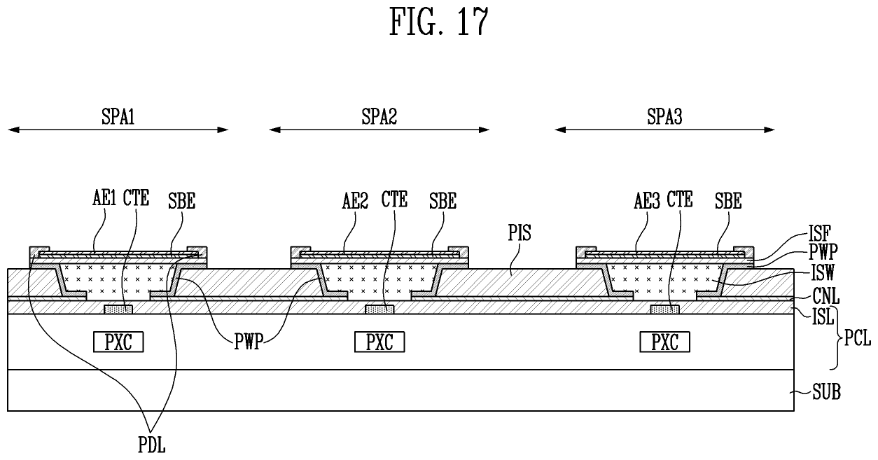

Referring to FIG. 17, the pixel defining films PDL may be formed on the first to third anode electrodes AE1 to AE3, respectively. The pixel defining films PDL may be formed to surround the edges of the first to third anode electrodes AE1 to AE3 and the edges of the sub-electrodes SBE, respectively. For example, the first to third anode electrodes AE1 to AE3 and the sub-electrodes SBE may be insulated from the partition wall patterns PWP and the cathode electrodes CE described below by the insulating films ISF and the pixel defining films PDL.

When the pixel defining films PDL are formed, the insulating patterns ISP (refer to FIG. 7) respectively overlapping the contact holes CNT may be formed on the first to third anode electrodes AE1 to AE3. For example, the pixel defining films PDL and the insulating patterns ISP may be formed of a same material and may be formed in a same process. The insulating patterns ISP may be formed to be spaced apart from the pixel defining films PDL.

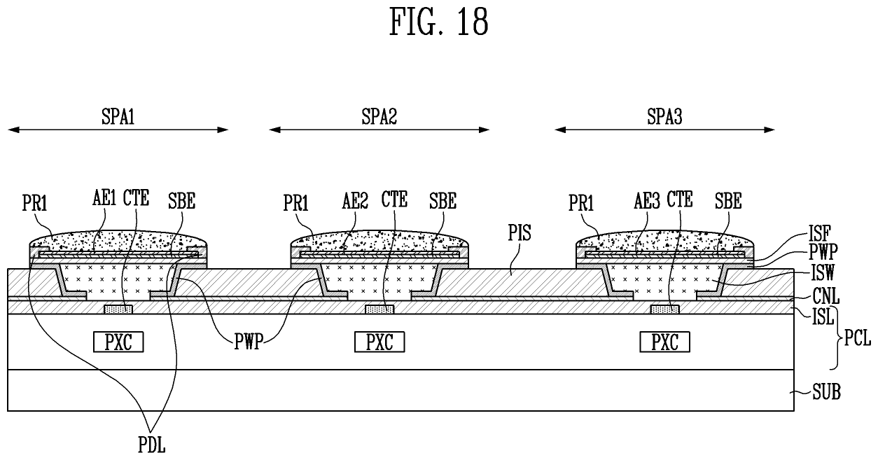

Referring to FIG. 18, first photoresist patterns PR1 may be formed on pixel defining layers PDL and first to third anode electrodes AE1 to AE3, respectively. Each of the first photoresist patterns PR1 may cover configurations disposed in the first to third sub-pixel areas SPA1 to SPA3 except for the preliminary insulating layer PIS.

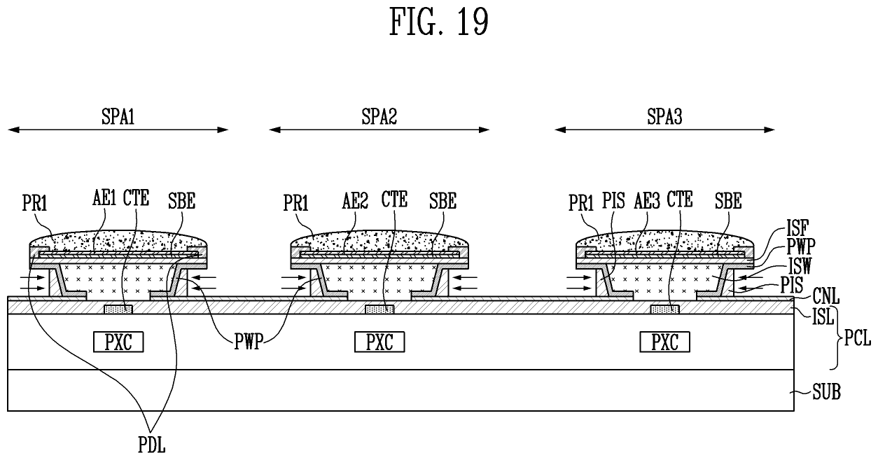

Referring to FIG. 19, the preliminary insulating layer PIS may be entirely removed using the first photoresist patterns PR1. For example, components except for the preliminary insulating layer PIS may be protected using the first photoresist patterns PR1, and the preliminary insulating layer PIS may be entirely etched.

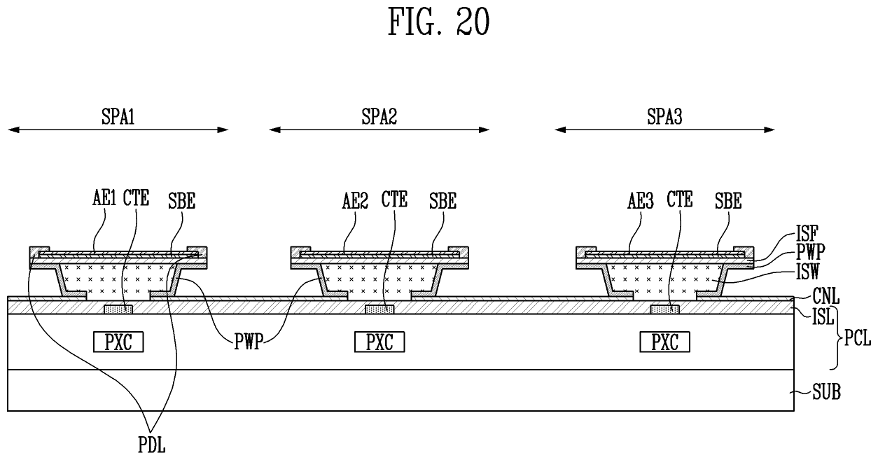

Referring to FIG. 20, the first photoresist patterns PR1 may be removed. Since the preliminary insulating layer PIS is entirely etched, only the partition wall patterns PWP may be disposed on the connection line CNL.

Since each of the insulating films ISF, the first to third anode electrodes AE1 to AE3, and the sub-electrodes SBE has the planar area greater than the area of each of the insulating partition walls ISW in a plan view, each of the insulating films ISF, the first to third anode electrodes AE1 to AE3, and the sub-electrodes SBE may have a tip structure of which a side surface protrudes further than the insulating partition wall ISW. Each of the insulating partition walls ISW may be formed in a shape in which the planar area decrease in a direction to the insulating layer ISL.

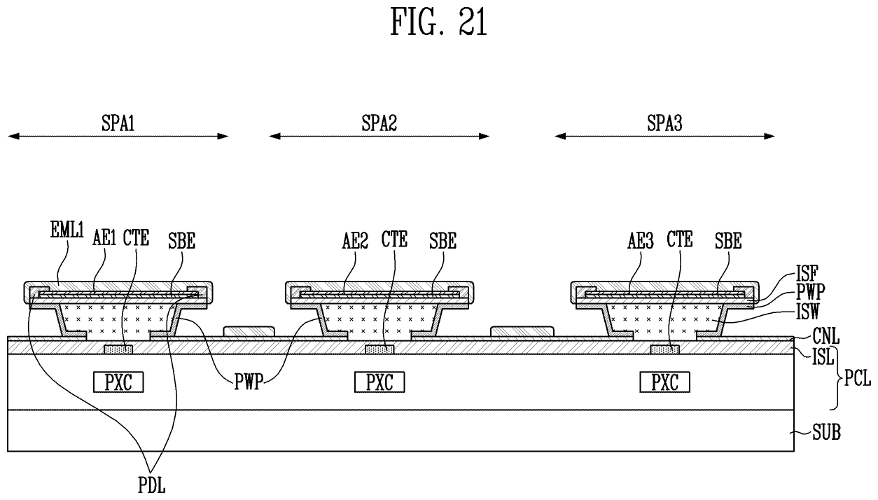

Referring to FIG. 21, the first emission layer EML1 may be formed on the first to third anode electrodes AE1 to AE3, the pixel defining layers PDL, and the connection line CNL. The first emission layer EML1 may be entirely formed in the first to third sub-pixel areas SPA1 to SPA3 without a separate mask. The first emission layer EML1 may not have an entirely extended shape, and may have a disconnected structure between the first to third sub-pixel areas SPA1 to SPA3 by the tip structure.

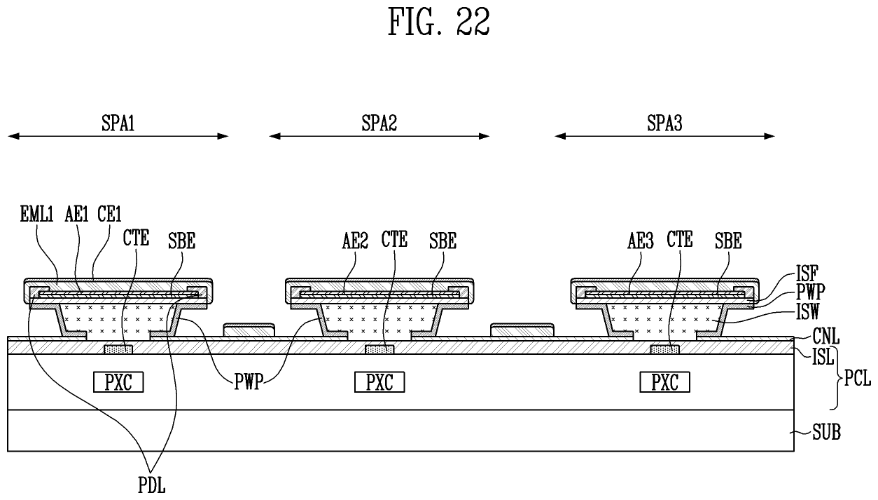

Referring to FIG. 22, the first cathode electrode CE1 may be formed on the first emission layer EML1. The first cathode electrode CE1 may also be entirely formed in the first to third sub-pixel areas SPA1 to SPA3 without a separate mask. The first cathode electrode CE1 also may not have an entirely extended shape, and may have a disconnected structure between the first to third sub-pixel areas SPA1 to SPA3 by the tip structure.

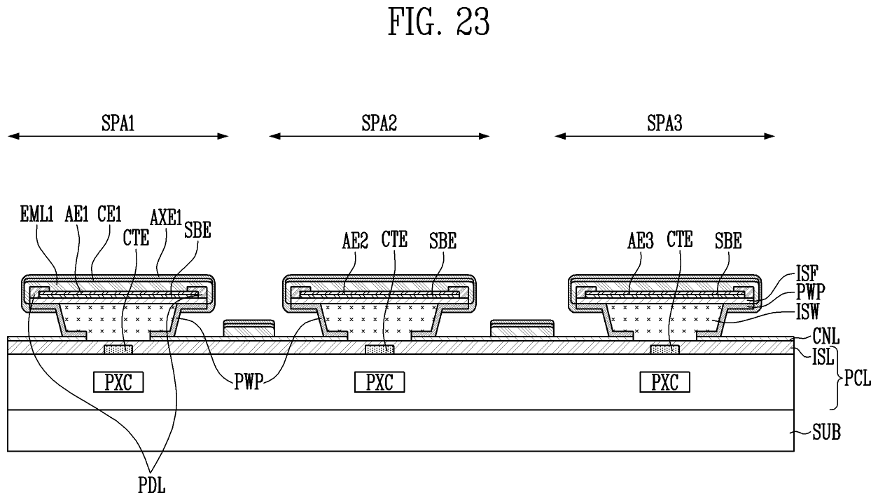

Referring to FIG. 23, a first auxiliary electrode AXE1 may be formed on the first cathode electrode CE1. The first auxiliary electrode AXE1 may entirely contact the first cathode electrode CE1. The first auxiliary electrode AXE1 may be entirely formed in the first to third sub-pixel areas SPA1 to SPA3 without a separate mask. The first auxiliary electrode AXE1 may not have an entirely extended shape, and may have a disconnected structure between the first to third sub-pixel areas SPA1 to SPA3 by the tip structure.

However, the first auxiliary electrode AXE1 may surround a portion of the first emission layer EML1, the first cathode electrode CE1, and the partition wall pattern PWP on the insulating partition wall ISW. For example, the first auxiliary electrode AXE1 may extend from an upper surface of the first cathode electrode CE1 to a portion where the partition wall pattern PWP is disposed and may be deposited, and thus the partition wall pattern PWP and the first auxiliary electrode AXE1 may contact (directly contact) each other.

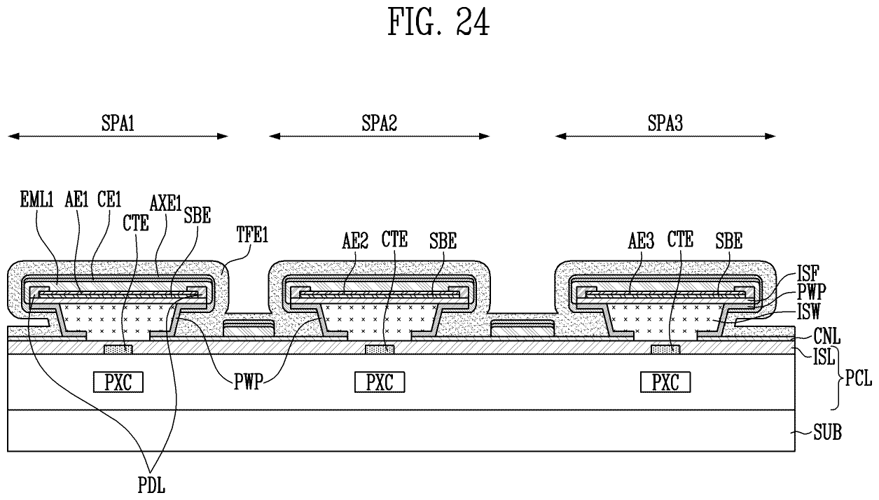

Referring to FIG. 24, a first encapsulation layer TFE1 may be formed on the first auxiliary electrode AXE1. The first encapsulation layer TFE1 may be entirely formed in the first to third sub-pixel areas SPA1 to SPA3. The first encapsulation layer TFE1 may have an entirely extended shape and may entirely cover lower components.

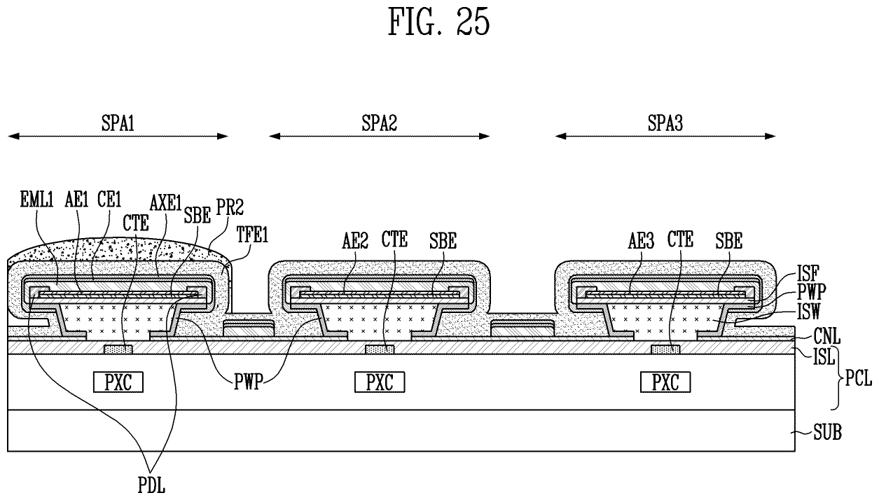

Referring to FIG. 25, a second photoresist pattern PR2 may be formed in the first sub-pixel area SPA1. The second photoresist pattern PR2 may overlap the first sub-pixel area SPA1 in a plan view, and may entirely cover configurations (for example, the first emission layer EML1, the first cathode electrode CE1, the first auxiliary electrode AXE1, and the first encapsulation layer TFE1) disposed in the first sub-pixel arca SPA1.

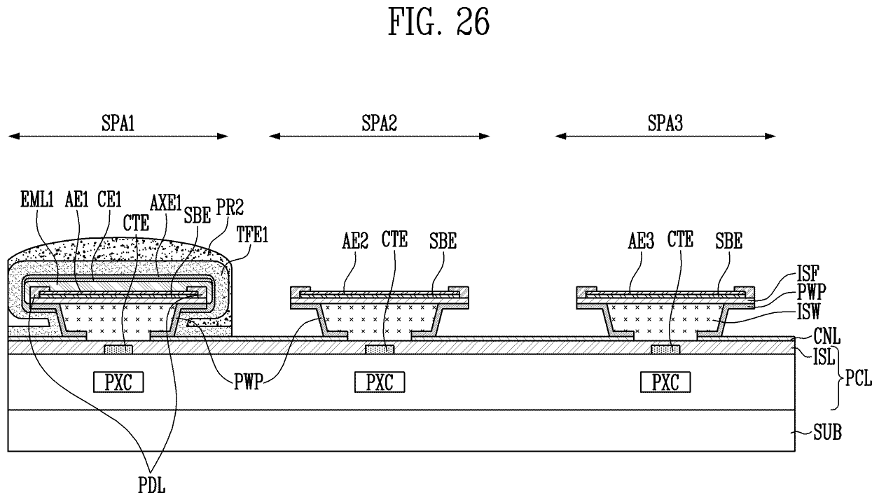

Referring to FIG. 26, the first emission layer EML1, the first cathode electrode CE1, the first auxiliary electrode AXE1, and the first encapsulation layer TFE1 in the second and third sub-pixel areas SPA2 and SPA3 may be removed using the second photoresist pattern PR2. For example, the first emission layer EML1, the first cathode electrode CE1, the first auxiliary electrode AXE1, and the first encapsulation layer TFE1 in the first sub-pixel arca SPA1 may be protected, and the remaining first emission layer EML1, first cathode electrode CE1, first auxiliary electrode AXE1, and first encapsulation layer TFE1 may be etched, by using the second photoresist pattern PR2.

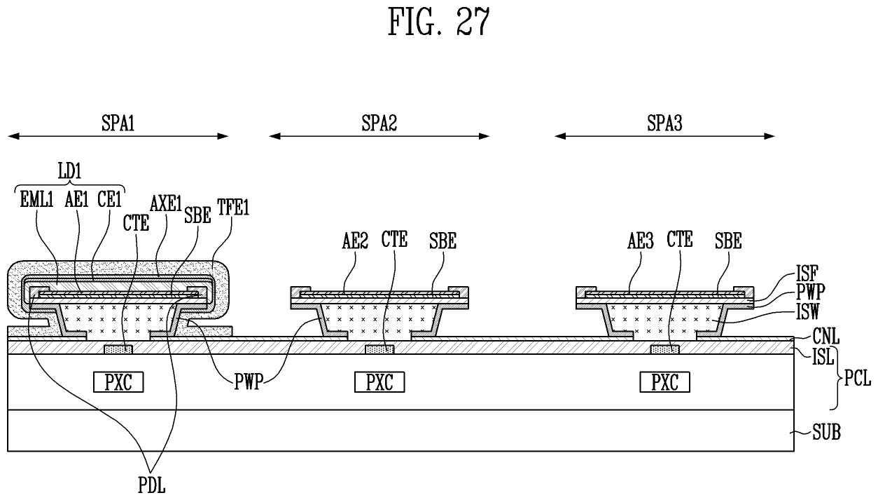

Referring to FIG. 27, the second photoresist pattern PR2 may be removed. Accordingly, only the first emission layer EML1, the first cathode electrode CE1, the first auxiliary electrode AXE1, and the first encapsulation layer TFE1 in the first sub-pixel area SPA1 may remain.

In the first sub-pixel area SPA1, the first anode electrode AE1, the first emission layer EML1, and the first cathode electrode CE1 may form the first light emitting element LD1. The first light emitting element LD1 may protrude laterally relative to the insulating partition wall ISW to form a tip structure.

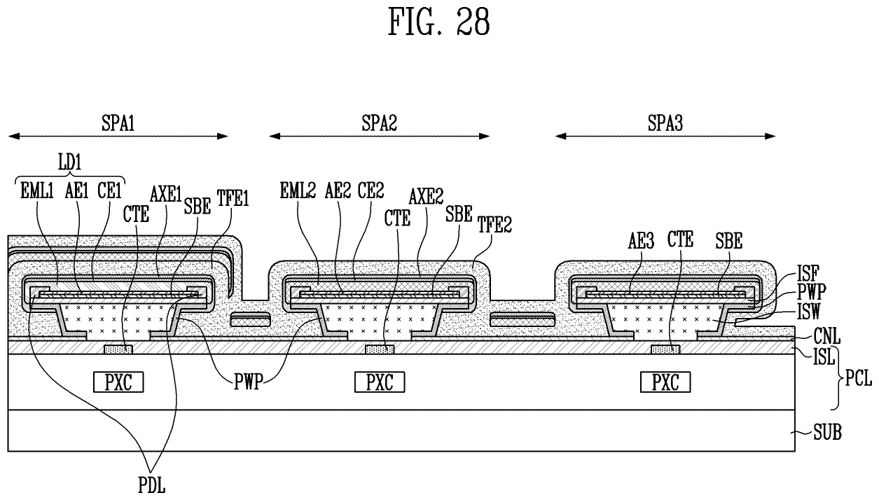

Referring to FIG. 28, the second emission layer EML2 may be formed on the first encapsulation layer TFE1, the second and third anode electrodes AE2 and AE3, the pixel defining films PDL, and the connection line CNL. The second emission layer EML2 may be disposed on the first encapsulation layer TFE1 in the first sub-pixel area SPA1, and may be disposed on the second and third anode electrodes AE2 and AE3 in the second and third sub-pixel areas SPA2 and SPA3, respectively.

The second emission layer EML2 may be entirely formed in the first to third sub-pixel areas SPA1 to SPA3 without a separate mask. The second emission layer EML2 may not have an entirely extended shape, and may have a disconnected structure between the first to third sub-pixel areas SPA1 to SPA3 by the tip structure, similarly to the first emission layer EML1.

Similarly to the first cathode electrode CE1, the first auxiliary electrode AXE1, and the first encapsulation layer TFE1, the second cathode electrode CE2 may be formed on the second emission layer EML2, the second auxiliary electrode AXE2 may be formed on the second cathode electrode CE2, and the second encapsulation layer TFE2 may be formed on the second auxiliary electrode AXE2.

The second auxiliary electrode AXE2 may surround a portion of the second emission layer EML2, the second cathode electrode CE2, and the partition wall pattern PWP on the insulating partition wall ISW in the second and third sub-pixel areas SPA2 and SPA3. For example, the second auxiliary electrode AXE2 may extend from an upper surface of the second cathode electrode CE2 in the second sub-pixel area SPA2 to a portion where the partition wall pattern PWP is disposed and may be deposited, and thus the partition wall pattern PWP and the second auxiliary electrode AXE2 may contact (e.g., directly contact) each other.

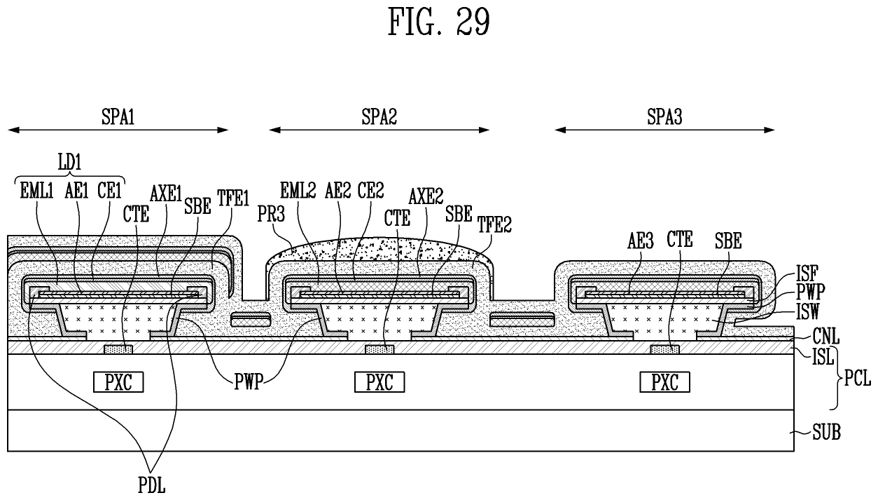

Referring to FIG. 29, a third photoresist pattern PR3 may be formed in the second sub-pixel area SPA2. The third photoresist pattern PR3 may overlap the second sub-pixel area SPA2, and may entirely cover configurations (for example, the second emission layer EML2, the second cathode electrode CE2, the second auxiliary electrode AXE2, and the second encapsulation layer TFE2) disposed in the second sub-pixel area SPA2.

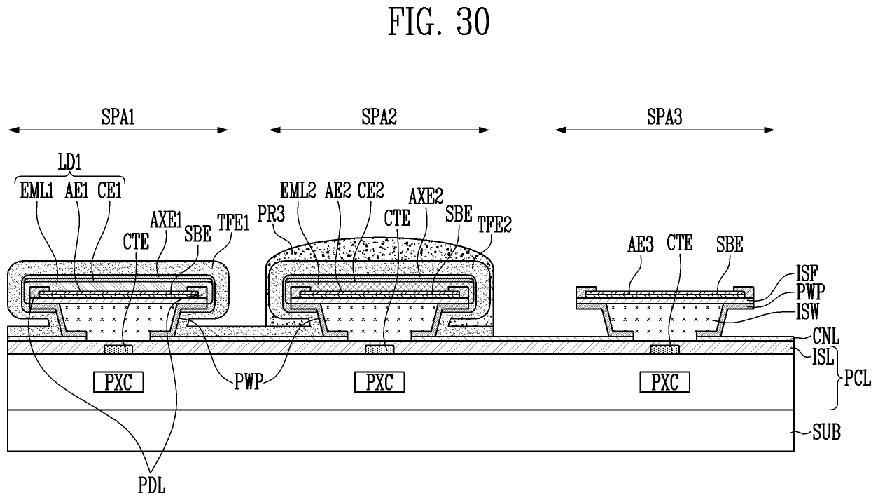

Referring to FIG. 30, the second emission layer EML2, the second cathode electrode CE2, the second auxiliary electrode AXE2, and the second encapsulation layer TFE2 in the first and third sub-pixel areas SPA1 and SPA3 may be removed using the third photoresist pattern PR3. For example, the second emission layer EML2, the second cathode electrode CE2, the second auxiliary electrode AXE2, and the second encapsulation layer TFE2 in the second sub-pixel area SPA2 may be protected, and the remaining second emission layer EML2, second cathode electrode CE2, second auxiliary electrode AXE2, and second encapsulation layer TFE2 may be etched, by using the third photoresist pattern PR3. The second encapsulation layer TFE2 may be etched so as to be connected to (for example, so as not to be spaced apart from) the first encapsulation layer TFE1.

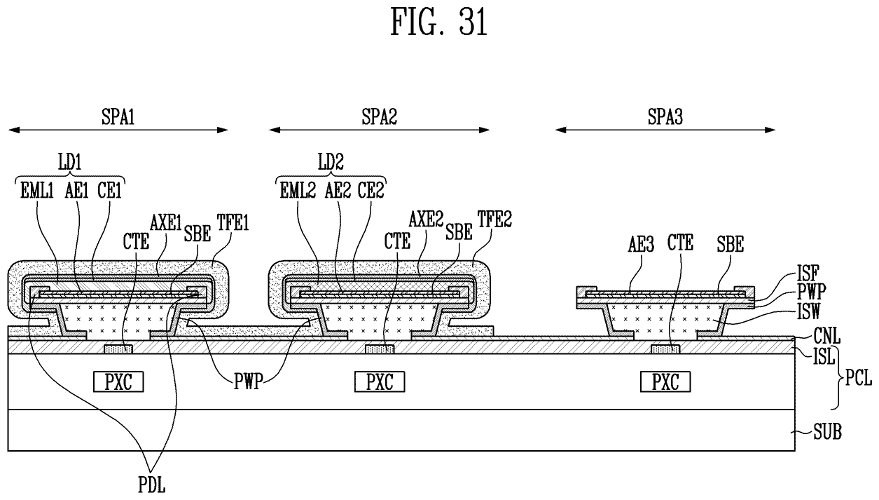

Referring to FIG. 31, the third photoresist pattern PR3 may be removed. Accordingly, only the second emission layer EML2, the second cathode electrode CE2, the second auxiliary electrode AXE2, and the second encapsulation layer TFE2 in the second sub-pixel arca SPA2 may remain.

In the second sub-pixel area SPA2, the second anode electrode AE2, the second emission layer EML2, and the second cathode electrode CE2 may form the second light emitting element LD2. The second light emitting element LD2 may protrude laterally relative to the insulating partition wall ISW to form a tip structure.

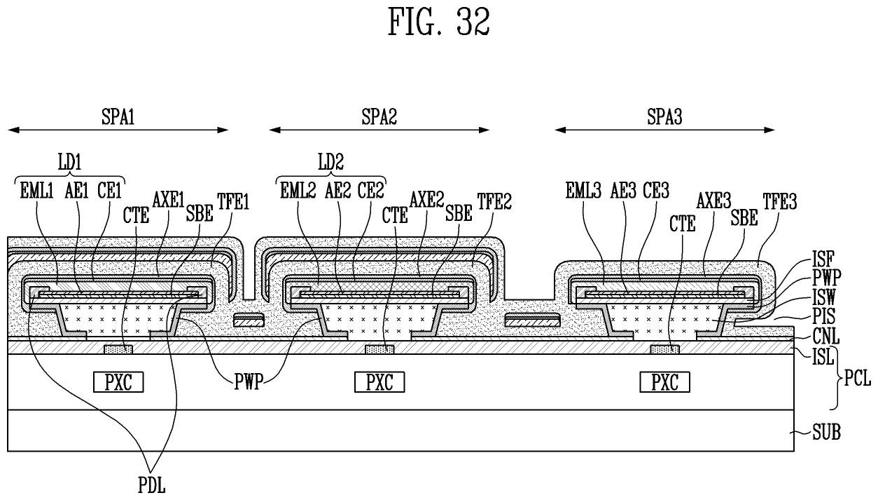

Referring to FIG. 32, the third emission layer EML3 may be formed on the first and second encapsulation layers TFE1 and TFE2, the third anode electrode AE3, the pixel definition film PDL, and the connection line CNL. The third emission layer EML3 may be disposed on the first and second encapsulation layers TFE1 and TFE2 in the first and second sub-pixel areas SPA1 and SPA2, respectively, and may be disposed on the third anode electrode AE3 in the third sub-pixel area SPA3.

The third emission layer EML3 may be entirely formed in the first to third sub-pixel areas SPA1 to SPA3 without a separate mask. The third emission layer EML3 may not have an entirely extended shape, and may have a disconnected structure between the first to third sub-pixel areas SPA1 to SPA3 by the tip structure, similarly to the second emission layer EML2.

Similarly to the second cathode electrode CE2, the second auxiliary electrode AXE2, and the second encapsulation layer TFE2, the third cathode electrode CE3 may be formed on the third emission layer EML3, the third auxiliary electrode AXE3 may be formed on the third cathode electrode CE3, and the third encapsulation layer TFE3 may be formed on the third auxiliary electrode AXE3.

The third auxiliary electrode AXE3 may surround a portion of the third emission layer EML3, the third cathode electrode CE3, and the partition wall pattern PWP on the insulating partition wall ISW in the third sub-pixel area SPA3. For example, the third auxiliary electrode AXE3 may extend from an upper surface of the third cathode electrode CE3 to a portion where the partition wall pattern PWP is disposed and may be deposited, and thus the partition wall pattern PWP and the third auxiliary electrode AXE3 may contact (e.g., directly contact).

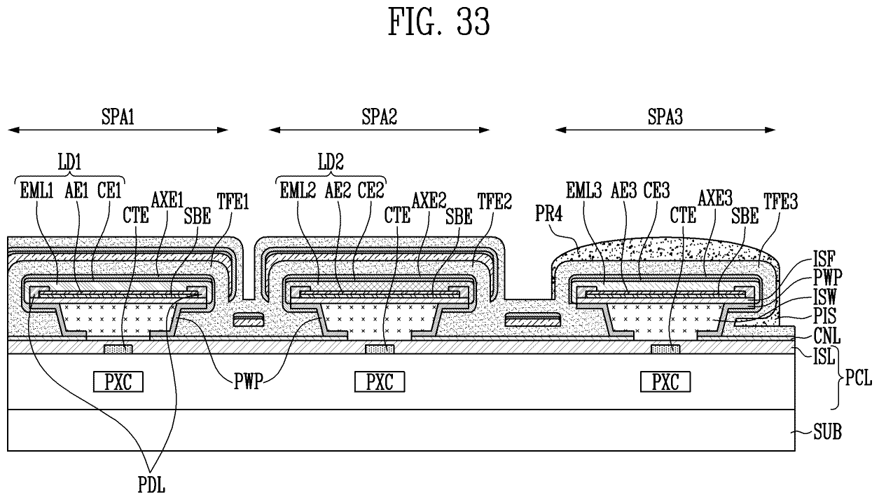

Referring to FIG. 33, a fourth photoresist pattern PR4 may be formed in the third sub-pixel area SPA3. The fourth photoresist pattern PR4 may overlap the third sub-pixel area SPA3, and may entirely cover configurations (for example, the third emission layer EML3, the third cathode electrode CE3, the third auxiliary electrode AXE3, and the third encapsulation layer TFE3) disposed in the third sub-pixel arca SPA3.

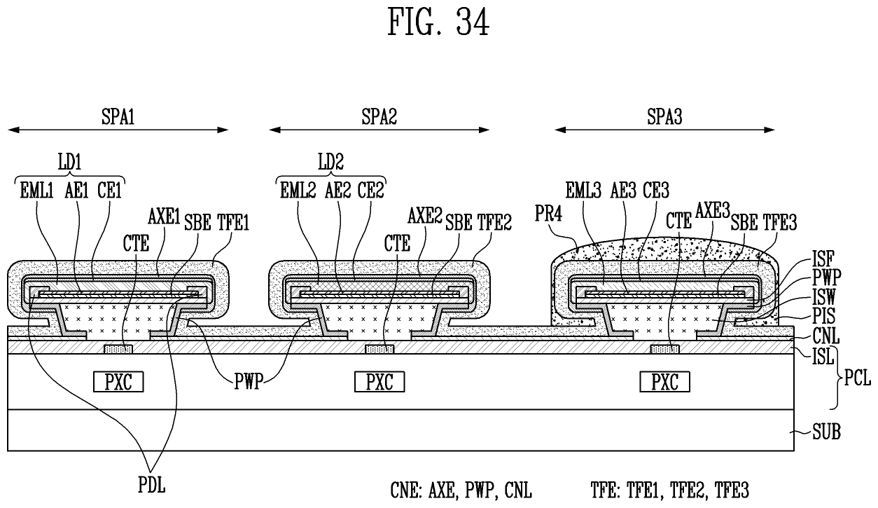

Referring to FIG. 34, the third emission layer EML3, the third cathode electrode CE3, the third auxiliary electrode AXE3, and the third encapsulation layer TFE3 in the first and second sub-pixel areas SPA1 and SPA2 may be removed using the fourth photoresist pattern PR4. For example, the third emission layer EML3, the third cathode electrode CE3, the third auxiliary electrode AXE3, and the third encapsulation layer TFE3 in the third sub-pixel area SPA3 may be protected, and the remaining third emission layer EML3, third cathode electrode CE3, third auxiliary electrode AXE3, and third encapsulation layer TFE3 may be etched, by using the fourth photoresist pattern PR4. The third encapsulation layer TFE3 may be etched so as to be connected to (for example, so as not to be spaced apart from) the second encapsulation layer TFE2.

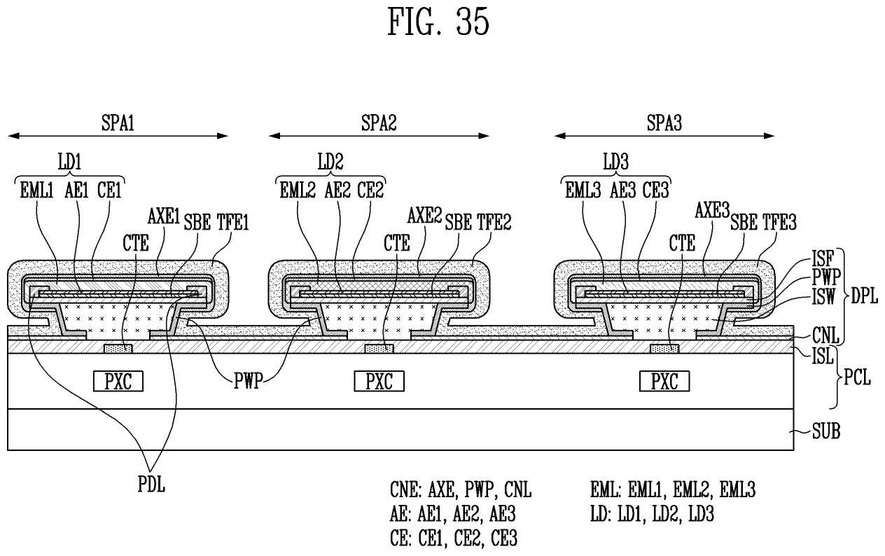

Referring to FIG. 35, the fourth photoresist pattern PR4 may be removed. Accordingly, only the third emission layer EML3, the third cathode electrode CE3, the third auxiliary electrode AXE3, and the third encapsulation layer TFE3 in the third sub-pixel area SPA3 may remain.

In the third sub-pixel area SPA3, the third anode electrode AE3, the third emission layer EML3, and the third cathode electrode CE3 may form the third light emitting element LD3. The third light emitting element LD3 may protrude laterally relative to the insulating partition wall ISW to form a tip structure.

Accordingly, the display element layer DPL including the insulating partition walls ISW, the insulating films ISF, the first to third anode electrodes AE1 to AE3, the first to third emission layers EML1 to EML3, the first to third cathode electrodes CE1 to CE3, the connection electrode CNE, the sub-electrodes SBE, the pixel defining films PDL, and the encapsulation layer TFE may be formed.

In an embodiment, as the first to third auxiliary electrodes AXE1 to AXE3, the partition wall patterns PWP, and the connection line CNL may be entirely extended while contacting each other, the connection electrode CNE including the first to third auxiliary electrodes AXE1 to AXE3, the partition wall patterns PWP, and the connection line CNL may be formed. The connection electrode CNE may be connected to the cathode electrode CE, may entirely surround the cathode electrode CE and the insulating partition wall ISW, and may electrically connect the cathode electrodes CE spaced apart from each other.

In an embodiment, as the anode electrode AE is spaced apart from the insulating layer ISL by the insulating partition wall ISW and protrudes, in case that the emission layer EML is entirely deposited on the anode electrode AE, a shadow effect in which deposition is not performed well in a shadowed portion may be prevented. Accordingly, the more uniform thickness of emission layer EML may be formed in a sub-pixel area. By connecting the cathode electrodes CE to each other, a step coverage problem that deposition is not performed well partially may be prevented by using the auxiliary electrode AXE, the partition wall pattern PWP, and the connection line CNL connected while contacting each other rather than connecting the cathode electrodes CE as a single extended structure. For example, since the disconnection and a resistance increase due to the step coverage may be prevented, the connection electrode CNE may stably connect the cathode electrodes CE to each other. Therefore, the reliability of the display device may be improved.

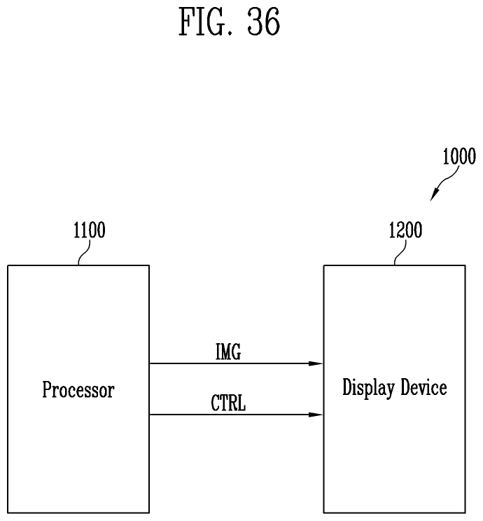

FIG. 36 is a schematic block diagram illustrating an embodiment of a display system.

Referring to FIG. 36, the display system 1000 may include a processor 1100 and a display device 1200.

The processor 1100 may perform various tasks and calculations. In embodiments, the processor 1100 may include an application processor, a graphics processor, a microprocessor, a central processing unit (CPU), and the like. The processor 1100 may be connected to other components of the display system 1000 through a bus system to control the other components.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1, and the image data IMG and the control signal CTRL may be provided as the input image data IMG and the control signal CTRL of FIG. 1, respectively.

The display system 1000 may include a computing system providing an image display function, such as a smart watch, a mobile phone, a smart phone, a portable computer, a tablet personal computer (PC), a watch phone, an automotive display, smart glasses, a portable multimedia player (PMP), a navigation device, and an ultra mobile personal computer (UMPC). The display system 1000 may include at least one of a head mounted display (HMD) device, a virtual reality (VR) device, a mixed reality (MR) device, and an augmented reality (AR) device.

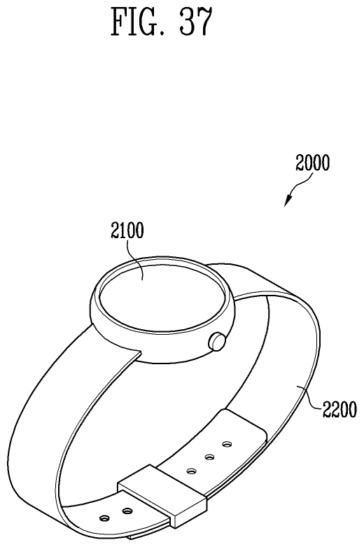

FIGS. 37 to 40 are perspective views illustrating application examples of the display system of FIG. 36.

Referring to FIG. 37, the display system 1000 of FIG. 36 may be applied to a smart watch 2000 including a display unit 2100 and a strap unit 2200.

The smart watch 2000 may be a wearable electronic device. For example, the smart watch 2000 may have a structure in which the strap unit 2200 can be mounted on a user's wrist. Here, the display system 1000 and/or the display device 1200 may be applied to the display unit 2100, and image data including time information may be provided to a user.

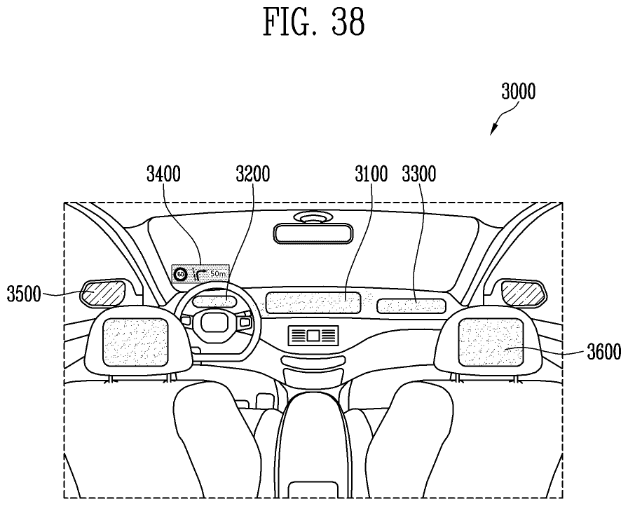

Referring to FIG. 38, the display system 1000 of FIG. 36 may be applied to an automotive display system 3000. Here, the automotive display system 3000 may include a computing system provided inside and/or outside a vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear seat displays 3600 provided in a vehicle.

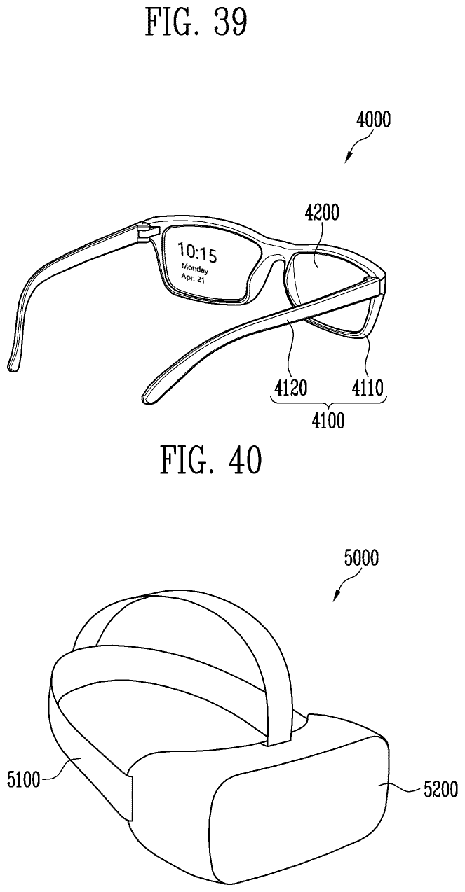

Referring to FIG. 39, the display system 1000 of FIG. 36 may be applied to smart glasses 4000. The smart glasses 4000 may be a wearable electronic device that may be worn on a user's head. For example, the smart glasses 4000 may be a wearable device for augmented reality.

The smart glasses 4000 may include a frame 4100 and a lens unit 4200. The frame 4100 may include a housing 4110 that supports the lens unit 4200 and a leg unit 4120 for the user to wear. The leg unit 4120 may be connected to the housing 4110 through a hinge and may be folded or unfolded relative to the housing 4110.

A battery, a touch pad, a microphone, a camera, and the like may be built in the frame 4100. A projector that outputs light, a processor that controls a light signal, and the like may be built in the frame 4100.

The lens unit 4200 may include an optical member that transmits or reflects light. For example, the lens unit 4200 may include glass, a transparent synthetic resin, or the like.

In order for user's eyes to recognize visual information, the lens unit 4200 may reflect an image by the light signal transmitted from the projector of the frame 4100 by a rear surface (for example, a surface of a direction facing the user's eyes) of the lens unit 4200. For example, the user may recognize visual information such as time and date displayed on the lens unit 4200. The projector and/or the lens unit 4200 may be a type of display device. The display device 1200 may be applied to the projector and/or the lens unit 4200.

Referring to FIG. 40, the display system 1000 of FIG. 36 may be applied to a head mounted display device 5000.

The head mounted display device 5000 may be a wearable electronic device that may be worn on a user's head. For example, the head mounted display device 5000 may be a wearable device for virtual reality or mixed reality.

The head mounted display device 5000 may include a head mount band 5100 and a display device receiving case 5200. The head mount band 5100 may be connected to the display device receiving case 5200. The head mount band 5100 may include a horizontal band and/or a vertical band for fixing the head mounted display device 5000 to a user's head. The horizontal band may be configured to surround a side portion of the user's head, and the vertical band may be configured to surround an upper portion of the user's head. However, the disclosure is not limited thereto. For example, the head mount band 5100 may be implemented in a form of a glasses frame, a helmet, or the like.

The display device receiving case 5200 may receive the display system 1000 and/or the display device 1200.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
an anode electrode disposed on a substrate;
an emission layer disposed on the anode electrode;
a cathode electrode disposed on the emission layer;
an insulating partition wall disposed between the substrate and the anode electrode, overlapping the anode electrode in a plan view, and having an area less than an area of the anode electrode in a plan view; and
a connection electrode connected to the cathode electrode, generally surrounding the emission layer, the cathode electrode, and the insulating partition wall, and extending on the substrate.

2. The display device according to claim 1, further comprising:
an insulating layer disposed between the substrate and the insulating partition wall.

3. The display device according to claim 2, wherein
the insulating partition wall protrudes from the insulating layer, and
the anode electrode is spaced apart from the insulating layer by the insulating partition wall.

4. The display device according to claim 2, wherein the connection electrode comprises:
an auxiliary electrode disposed on the cathode electrode and directly contacting the cathode electrode;
a partition wall pattern surrounding the insulating partition wall and connected to the auxiliary electrode; and
a connection line disposed between the insulating layer and the partition wall pattern, extending on the insulating layer, and connected to the partition wall pattern.

5. The display device according to claim 4, wherein the auxiliary electrode includes a transparent conductive oxide (TCO).

6. The display device according to claim 4, further comprising:
an insulating film disposed between the insulating partition wall and the anode electrode and disposed between the partition wall pattern and the anode electrode.

7. The display device according to claim 6, further comprising:
a sub-electrode disposed between the anode electrode and the insulating film.

8. The display device according to claim 7, further comprising:
a circuit element disposed between the substrate and the insulating layer and connected to at least one of the anode electrode and the sub-electrode.

9. The display device according to claim 8, wherein a contact hole for connection between the anode electrode and the sub-electrode and the circuit element is defined in the insulating film, the insulating partition wall, and the insulating layer.

10. The display device according to claim 9, further comprising:
a pixel defining film surrounding an edge of the anode electrode and contacting the insulating film.

11. The display device according to claim 10, further comprising:
an insulating pattern disposed between the anode electrode and the emission layer and overlapping the contact hole in a plan view.

12. The display device according to claim 11, wherein the insulating pattern and the pixel defining film include a same material.

13. A display device comprising:
anode electrodes disposed on a substrate, respectively overlapping sub-pixel areas in a plan view, and spaced apart from each other;
emission layers respectively disposed on the anode electrodes;
cathode electrodes respectively disposed on the emission layers and spaced apart from each other;
insulating partition walls disposed between the substrate and the anode electrodes, respectively overlapping the anode electrodes in a plan view, and spaced apart from each other; and
a connection electrode connecting the cathode electrodes to each other.

14. The display device according to claim 13, wherein the connection electrode comprises:
auxiliary electrodes respectively disposed on the cathode electrodes and respectively directly contacting the cathode electrodes;
partition wall patterns respectively surrounding the insulating partition walls and respectively connected to the auxiliary electrodes overlapping each other in a plan view; and
a connection line disposed between the substrate and the partition wall patterns and connecting the partition wall patterns to each other.

15. The display device according to claim 14, wherein the connection line is disposed between the substrate and the insulating partition walls and entirely extends on the substrate except for portions overlapping the insulating partition walls in a plan view.

16. An electronic device comprising:
a processor to provide input image data; and
a display device to display an image based on the input image data,
wherein the display device comprises:
an anode electrode disposed on a substrate;
an emission layer disposed on the anode electrode;
a cathode electrode disposed on the emission layer;
an insulating partition wall disposed between the substrate and the anode electrode, overlapping the anode electrode in a plan view, and having an area less than an area of the anode electrode in a plan view; and
a connection electrode connected to the cathode electrode, generally surrounding the emission layer, the cathode electrode, and the insulating partition wall, and extending on the substrate.

17. The electronic device of claim 16, wherein the electronic device is at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.
